(19) United States
(12) Patent Application Publication
(10) Pub. No.: US 2024/0412913 A1
(43) Pub. Date: Dec. 12, 2024

(54) MULTI-POLE INDUCTOR STRUCTURES WITH INHERENT HIGH ISOLATION

(71) Applicant: QUALCOMM Incorporated, San Diego, CA (US)

(72) Inventors: Lisette ZHANG, Vista, CA (US); Med NARIMAN, Ladera Ranch, CA (US); Chinmaya MISHRA, San Diego, CA (US); Faramarz SABOURI, San Diego, CA (US); Gurkanwal Singh SAHOTA, Rancho Santa Fe, CA (US)

(21) Appl. No.: 18/332,247

(22) Filed: Jun. 9, 2023

(51) Int. Cl. H01F 21/12; H01F 17/00; H01F 27/04; H01F 27/29

(52) U.S. Cl. CPC H01F 21/12; H01F 17/0013; H01F 27/04; H01F 27/29; H01F 2021/125

(57) ABSTRACT

An inductor structure has a first terminal and a second terminal, and includes a conductor path between the first terminal and the second terminal. The conductor path includes a first inductor, a second inductor, a third inductor, a fourth inductor, a fifth inductor, and a sixth inductor. The conductor path may be configured such that, when a current flows from the first terminal to the second terminal, the current flows in a first direction in the first inductor, the third inductor, and the fifth inductor, and the current flows in a second direction in the second inductor, the fourth inductor, and the sixth inductor. The first direction may be clockwise and the second direction may be counterclockwise, or vice versa.

### BACKGROUND

### Field

Aspects of the present disclosure relate generally to wireless communications, and, more particularly, to inductor structures in a wireless device.

### Background

A wireless device may include a transceiver for transmitting and/or receiving signals via one or more antennas. The transceiver may include inductors in various components of the transceiver. For example, the transceiver may include inductors in power amplifiers, low-noise amplifiers, oscillators (e.g., voltage-controlled oscillators (VCOs)), filters, impedance-matching networks, transformers, etc. A challenge with using inductors in the transceiver is that there is unwanted magnetic coupling between inductors in the transceiver, which degrades the performance of the transceiver. The unwanted magnetic coupling may worsen as components in the transceiver scale down and/or are more closely spaced together.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to an apparatus. The apparatus includes an inductor structure having a first terminal and a second terminal. The inductor structure includes a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a first direction in the first inductor, the third inductor, and the fifth inductor, and the current flows in a second direction in the second inductor, the fourth inductor, and the sixth inductor.

A second aspect relates to an apparatus. The apparatus includes am inductor structure having a first terminal and a second terminal. The inductor structure includes a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a same direction in the first inductor, the second inductor, the third inductor, the fourth inductor, the fifth inductor, and the sixth inductor.

A third aspect relates to an apparatus. The apparatus includes an inductor structure having a first terminal and a second terminal. The inductor structure includes a conductor path defined by a first loop portion partially enclosing a first area, a second loop portion partially enclosing a second area, a third loop portion partially enclosing a third area, the second loop portion positioned between the first loop portion and the third loop portion, a fourth loop portion partially enclosing a fourth area, the third loop portion positioned between the second loop portion and the fourth loop portion, a fifth loop portion partially enclosing a fifth area, the fourth loop portion positioned between the third loop portion and the fifth loop portion, and a sixth loop portion enclosing partially enclosing a sixth area, the fifth loop portion positioned between the third loop portion and the sixth loop portion. The first loop portion, the second loop portion, the third loop portion, the forth loop portion, the fifth loop portion, and the sixth loop portion are positioned in a circular arrangement such that a circumference of a circle passes through each of the first loop portion, the second loop portion, the third loop portion, the forth loop portion, the fifth loop portion, and the sixth loop portion.

A fourth aspect relates to a method of fabricating an inductor structure. The inductor structure includes a conductor path including first loop portion, a second loop portion, a third loop portion, a fourth loop portion, a fifth loop portion, and a sixth loop portion. The method includes patterning a first metal layer to form a first portion of the conductor path, the first portion including the first loop portion, the third loop portion, and the fifth loop portion. The method also includes forming one or more vias, wherein the one or more vias are coupled to the first portion of the conductor path. The method further includes patterning a second metal layer to form a second portion of the conductor path, the second portion including the second loop portion, the fourth loop portion, and the sixth loop portion, wherein the second metal layer is different from the first metal layer.

### BRIEF DESCRIPTION OF THE DRAWINGS

FIG. 1 is a diagram of an environment including an electronic device that includes a transceiver according to certain aspects of the present disclosure.

FIG. 2 shows an example of an electronic device including a transceiver and antennas according to certain aspects of the present disclosure.

FIG. 3 shows an example of a voltage-controlled oscillator (VCO) including an inductor according to certain aspects of the present disclosure.

FIG. 4A shows an example of a power amplifier (PA) according to certain aspects of the present disclosure

FIG. 4B shows an example of a differential PA according to certain aspects of the present disclosure.

FIG. 4C shows another example of a differential PA according to certain aspects of the present disclosure.

FIG. 5A shows an example of a low-noise amplifier (LNA) according to certain aspects of the present disclosure.

FIG. 5B shows another example of an LNA according to certain aspects of the present disclosure.

FIG. 5C shows yet another example of an LNA according to certain aspects of the present disclosure.

FIG. 5D shows still another example of an LNA according to certain aspects of the present disclosure.

FIG. 5E shows an example of a differential LNA according to certain aspects of the present disclosure.

FIG. 5F shows another example of a differential LNA according to certain aspects of the present disclosure.

FIG. 6 shows an example of unwanted magnetic coupling between components in a transceiver according to certain aspects of the present disclosure.

FIG. 7 shows an example of an inductor structure according to certain aspects of the present disclosure.

FIG. 8A shows an example of current flow in the inductor structure of FIG. 7 according to certain aspects of the present disclosure.

FIG. 8B shows another example of current flow in the inductor structure of FIG. 7 according to certain aspects of the present disclosure.

FIG. 9 is a circuit schematic representation of the inductor structure of FIG. 7 illustrating strong magnetic coupling between adjacent inductors in the inductor structure according to certain aspects of the present disclosure.

FIG. 10A shows an example of a first portion of the inductor structure of FIG. 7 formed from a first metal layer according to certain aspects of the present disclosure.

FIG. 10B shows an example of a second portion of the inductor structure of FIG. 7 formed from a second metal layer according to certain aspects of the present disclosure.

FIG. 11 shows an example of the inductor structure of FIG. 7 used as an inductor in a VCO according to certain aspects of the present disclosure.

FIG. 12 shows an example of a voltage-controlled capacitor located within the inductor structure of FIG. 7 according to certain aspects of the present disclosure.

FIG. 13 shows an example of the inductor structure of FIG. 7 used as an inductor in a PA according to certain aspects of the present disclosure.

FIG. 14 shows an example of input transistors located within the inductor structure of FIG. 7 according to certain aspects of the present disclosure.

FIG. 15 shows another example of the inductor structure of FIG. 7 used as an inductor in a PA according to certain aspects of the present disclosure.

FIG. 16 shows an example of input transistors and cascode transistors located within the inductor structure of FIG. 7 according to certain aspects of the present disclosure.

FIG. 17 shows another example of an inductor structure according to certain aspects of the present disclosure.

FIG. 18A shows an example of current flow in the inductor structure of FIG. 17 according to certain aspects of the present disclosure.

FIG. 18B shows another example of current flow in the inductor structure of FIG. 17 according to certain aspects of the present disclosure.

FIG. 19A shows an example of a first portion of the inductor structure of FIG. 17 formed from a first metal layer according to certain aspects of the present disclosure.

FIG. 19B shows an example of a second portion of the inductor structure of FIG. 17 formed from a second metal layer according to certain aspects of the present disclosure.

FIG. 20 shows an example of the inductor structure of FIG. 17 used as an inductor in an LNA according to certain aspects of the present disclosure.

FIG. 21 shows another example of the inductor structure of FIG. 17 used as an inductor in an LNA according to certain aspects of the present disclosure.

FIG. 22 is a flowchart illustrating a method of fabricating an inductor structure according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

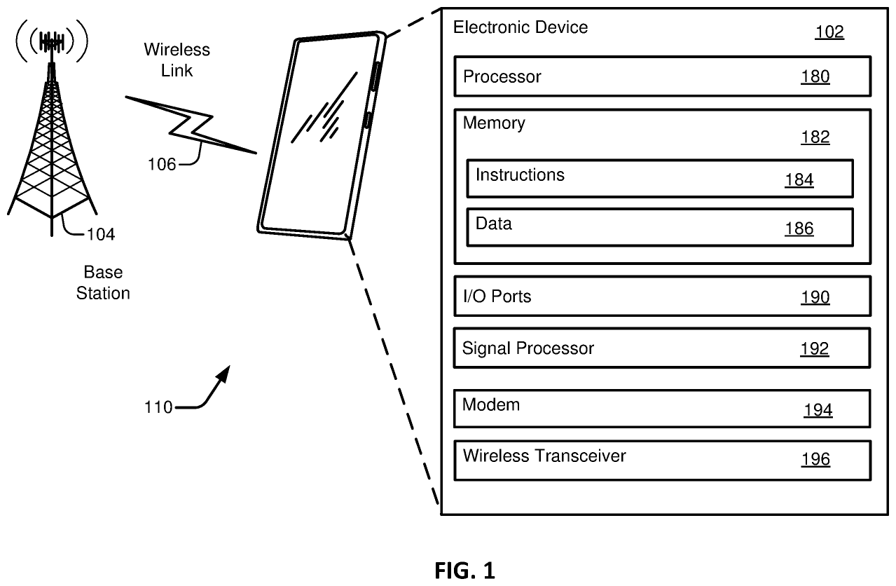

FIG. 1 is a diagram of an environment 100 including an electronic device 102 that includes a transceiver 196. In the environment 100, the electronic device 102 communicates with a base station 104 through a wireless link 106. As shown, the electronic device 102 is depicted as a smart phone. However, the electronic device 102 may be implemented as any suitable computing or other electronic device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 104 communicates with the electronic device 102 via the wireless link 106, which may be implemented as any suitable type of wireless link. Although depicted as a base station tower of a cellular radio network, the base station 104 may represent or be implemented as another device, such as a satellite, a terrestrial broadcast tower, an access point, a peer-to-peer device, a mesh network node, another electronic device generally as described above, and so forth. The wireless link 106 can include a downlink of data and/or control information communicated from the base station 104 to the electronic device 102. The wireless link 106 may also include an uplink of data and/or control information communicated from the electronic device 102 to the base station 104. The wireless link 106 may be implemented using any suitable communication protocol or standard, such as 3rd Generation Partnership Project Long-Term Evolution (3GPP LTE, 3GPP NR 5G), IEEE 802.11, IEEE 802.1, Bluetooth™M, and so forth.

The electronic device 102 includes a processor 180 and a memory 182. The memory 182 may be or form a portion of a computer readable storage medium. The processor 180 may include any type of processor, such as an application processor or a multi-core processor, that is configured to execute processor-executable instructions (e.g., code) stored by the memory 182. The memory 182 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 182 is implemented to store instructions 184, data 186, and other information of the electronic device 102, and thus when configured as or part of a computer readable storage medium, the memory 182 does not include transitory propagating signals or carrier waves.

The electronic device 102 may also include input/output (I/O) ports 190. The I/O ports 190 enable data exchanges or interaction with other devices, networks, or users or between components of the device.

The electronic device 102 may further include a signal processor (SP) 192 (e.g., such as a digital signal processor (DSP)). The signal processor 192 may function similar to the processor and may be capable of executing instructions and/or processing information in conjunction with the memory 182.

For communication purposes, the electronic device 102 also includes a modem 194, the transceiver 196, and one or more antennas. The transceiver 196 provides connectivity to respective networks and other electronic devices connected therewith using radio frequency (RF) signals. The transceiver 196 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

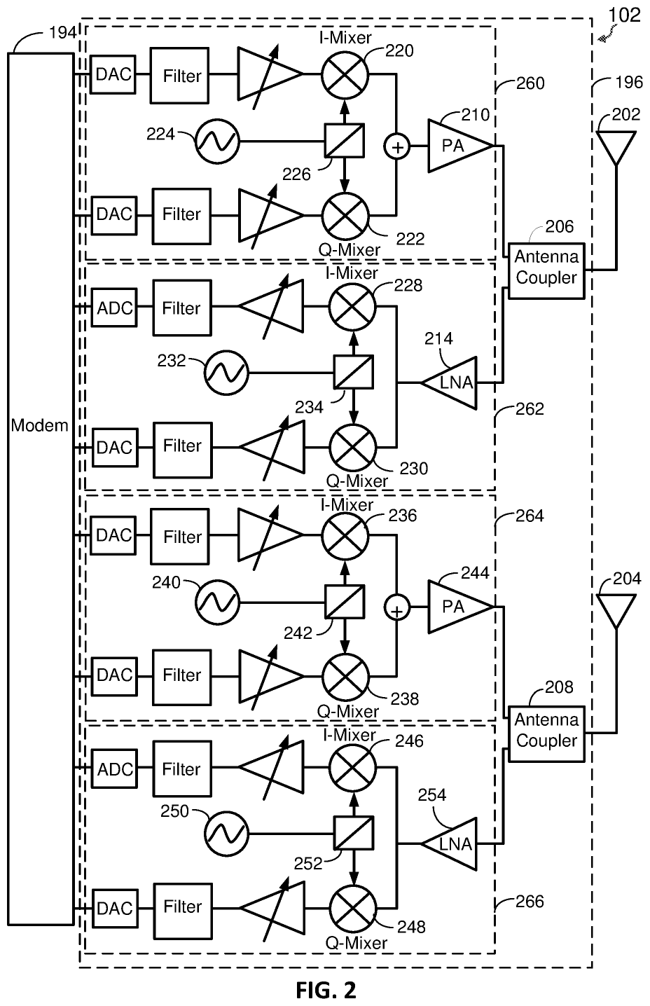

FIG. 2 shows an example in which the electronic device 102 includes the transceiver 196, the modem 194 (also referred to as a baseband processor), a first antenna 202, and a second antenna 204. The transceiver 196 may be coupled to the modem 194 via one or more signal lines. For example, in some implementations, the transceiver 196 may be coupled to the modem 194 via multiple signal lines arranged in parallel. The transceiver 196, the modem 194, and the antennas 202 and 204 or any combination thereof may be mounted on, formed on, and/or embedded in a substrate (e.g., a printed circuit board (PCB), a plastic laminate, a ceramic, any combination thereof, etc.). The transceiver 196 may be integrated on one or more chips. For example, in some implementations, the transceiver 196 may be integrated on multiple chips in a multi-chip module.

The transceiver 196 may be coupled to each of the antennas 202 and 204 via respective transmission lines (also referred to as feedlines). In certain aspects, the transmission lines may be implemented with metal traces formed on and/or embedded in the substrate. In some implementations, the antennas 202 and 204 may be integrated in an antenna module. Each of the antennas 202 and 204 may be implemented with a patch antenna, a dipole antenna, or another type of antenna. The antennas 202 and 204 may also be referred to as antenna elements or another term. Although two antennas are shown in FIG. 2, it is to be appreciated that the electronic device 102 may include additional antennas (e.g., an antenna array including multiple antennas).

The transceiver 196 may be configured to transmit one or more RF signals (e.g., to the base station 104) via one or more of the antennas 202 and 204. The transceiver 196 may also be configured to receive one or more RF signals (e.g., from the base station 104) via the one or more of the antennas 202 and 204. The transceiver 196 may transmit and/or receive RF signals using one or more wireless communication technologies, including, but not limited to, a third generation (3G) technology (e.g., CDMA), a fourth generation (4G) technology (also known as long term evolution (LTE)), a fifth generation (5G) technology, one or more technologies based on one or more IEEE 802.11 protocols (e.g., IEEE 802.11ac, IEEE 802.11n, IEEE 802.11ad, IEEE 802.11ax, IEEE 802.11ay, etc.), and/or one or more other technologies. The RF signals may be in a millimeter wave (mmW) frequency band and/or another frequency band. Examples of mmW frequency bands include mmW frequency bands used in fifth-generation standards.

In the example shown in FIG. 2, the transceiver 196 includes a first transmit circuit 260, a first receive circuit 262, and a first antenna coupler 206 coupling the first transmit circuit 260 and the first receive circuit 262 to the first antenna 202. The first antenna coupler 206 may include a diplexer and/or a duplexer.

In this example, the first transmit circuit 260 includes a first mixer 220, a second mixer 222, a first frequency synthesizer 224 (e.g., phase locked loop (PLL)), a first phase splitter 226, and a first power amplifier (PA) 210. The first frequency synthesizer 224 is configured to generate a first local oscillator (LO) signal, and the first phase splitter 226 is configured to generate an in-phase LO signal and a quadrature LO signal based on the first LO signal, in which the in-phase LO and the quadrature LO signal are 90 degrees apart. The first mixer 220 is configured to mix a first baseband signal or a first intermediate frequency (IF) signal with the in-phase LO signal to generate an in-phase RF signal, and the second mixer 222 is configured to mix a second baseband signal or a second IF signal with the quadrature LO signal to generate a quadrature RF signal. The in-phase RF signal and the quadrature RF signal are combined into a combined RF signal. The first PA 210 amplifies the combined RF signal, and the first antenna coupler 206 couples the amplified RF signal to the first antenna 202 for transmission. As shown in FIG. 2, the first transmit circuit 260 may include additional components such as filters, variable gain amplifiers, and digital-to-analog converters (DACs). It is to be appreciated that the first transmit circuit 260 may include additional components not shown in FIG. 2.

The first receive circuit 262 includes a first low-noise amplifier (LNA) 214, a third mixer 228, a fourth mixer 230, a second frequency synthesizer 232 (e.g., PLL), and a second phase splitter 234. The first LNA 214 is configured to receive an RF signal from the first antenna 202 through the first antenna coupler 206, and output the amplified RF signal. The second frequency synthesizer 232 is configured to generate a second LO signal, and the second phase splitter 234 is configured to generate an in-phase LO signal and a quadrature LO signal based on the second LO signal, in which the in-phase LO and the quadrature LO signal are 90 degrees apart. The third mixer 228 is configured to mix the amplified RF signal from the first LNA 214 with the in-phase LO signal to generate an in-phase baseband or IF signal, and the fourth mixer 230 is configured to mix the amplified RF signal from the first LNA 214 with the quadrature LO signal to generate an quadrature baseband or IF signal. The in-phase baseband or IF signal and the quadrature baseband or IF signal are processed by additional components in the first receive circuit 262 before being input to the modem 194. As shown in FIG. 2, the first receive circuit 262 may include additional components such as filters, variable gain amplifiers, and analog-to-digital converters (ADCs). It is to be appreciated that the first receive circuit 262 may include additional components not shown in FIG. 2.

In the example shown in FIG. 2, the transceiver 196 also includes a second transmit circuit 264, a second receive circuit 266, and a second antenna coupler 208 coupling the second transmit circuit 264 and the second receive circuit 266 to the second antenna 204. The second antenna coupler 208 may include a diplexer and/or a duplexer.

In this example, the second transmit circuit 260 includes a fifth mixer 236, a sixth mixer 238, a third frequency synthesizer 240 (e.g., PLL), a third phase splitter 242, and a second PA 244. The third frequency synthesizer 240 is configured to generate a third LO signal, and the third phase splitter 242 is configured to generate an in-phase LO signal and a quadrature LO signal based on the third LO signal, in which the in-phase LO and the quadrature LO signal are 90 degrees apart. The fifth mixer 236 is configured to mix a third baseband signal or a third IF signal with the in-phase LO signal to generate an in-phase RF signal, and the sixth mixer 238 is configured to mix a fourth baseband signal or a fourth IF signal with the quadrature LO signal to generate a quadrature RF signal. The in-phase RF signal and the quadrature RF signal are combined into a combined RF signal. The second PA 210 amplifies the combined RF signal, and the second antenna coupler 208 couples the amplified RF signal to the second antenna 204 for transmission. As shown in FIG. 2, the second transmit circuit 264 may include additional components such as filters, variable gain amplifiers, and digital-to-analog converters (DACs). It is to be appreciated that the second transmit circuit 264 may include additional components not shown in FIG. 2.

The second receive circuit 266 includes a second LNA 254, a seventh mixer 246, an eighth mixer 248, a fourth frequency synthesizer 250 (e.g., PLL), and a fourth phase splitter 252. The second LNA 254 is configured to receive an RF signal from the second antenna 204 through the second antenna coupler 208, and output the amplified RF signal. The fourth frequency synthesizer 250 is configured to generate a fourth LO signal, and the fourth phase splitter 252 is configured to generate an in-phase LO signal and a quadrature LO signal based on the fourth LO signal, in which the in-phase LO and the quadrature LO signal are 90 degrees apart. The seventh mixer 246 is configured to mix the amplified RF signal from the second LNA 254 with the in-phase LO signal to generate an in-phase baseband or IF signal, and the eighth mixer 248 is configured to mix the amplified RF signal from the second LNA 254 with the quadrature LO signal to generate a quadrature baseband or IF signal. The in-phase baseband or IF signal and the quadrature baseband or IF signal are processed by additional components in the second receive circuit 266 before being input to the modem 194. As shown in FIG. 2, the second receive circuit 266 may include additional components such as filters, variable gain amplifiers, and analog-to-digital converters (ADCs). It is to be appreciated that the second transmit circuit 264 may include additional components not shown in FIG. 2.

Thus, in this example, the first transmit circuit 260 and the first receive circuit 262 may be used to transmit and/or receive RF signals via the first antenna 202 (e.g., for a first channel), and the second transmit circuit 264 and the second receive circuit 266 may be used to transmit and/or receive RF signals via the second antenna 204 (e.g., for a second channel). It is to be appreciated that the transceiver 196 may include one or more additional transmit circuits and one or more additional receive circuits to transmit and/or receive RF signals via one or more additional antennas not shown in FIG. 2. It is also to be appreciated that one or more of the components shown in FIG. 2 may be differential is some implementations. For example, in some implementations, the PAs 210 and 244 may each have differential inputs and/or differential outputs.

Various components in the transceiver 196 may include one or more inductors. For example, each of the PAs 210 and 244 may include one or more inductors, each of the LNAs 214 and 254 may include one or more inductors, and each of the frequency synthesizers 224, 232, 240, and 250 may include one or more inductors. Also, each of the antenna couplers 206 and 208 may include one or more inductors.

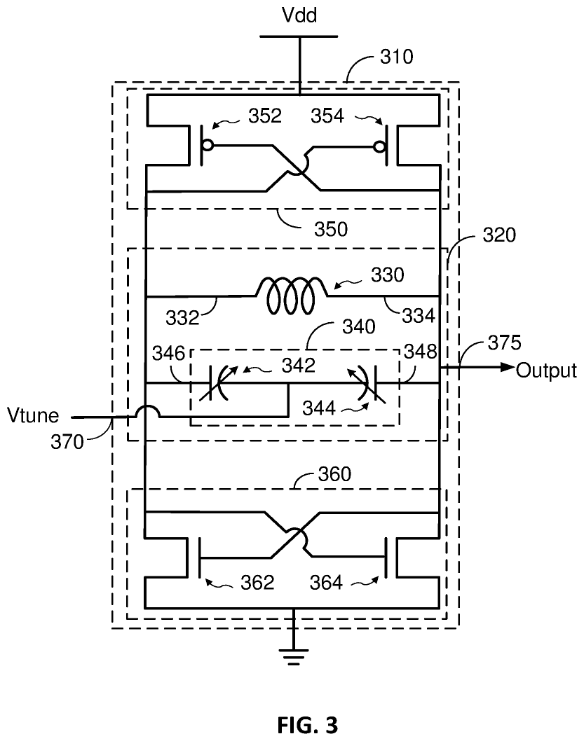

For example, FIG. 3 shows an example of a voltage-controlled oscillator (VCO) 310. Each of the frequency synthesizers 224, 232, 240, and 250 may include a separate instance of the VCO 310 to generate the respective LO signal. In this example, the VCO 310 includes an inductor-capacitor (LC) tank 320, a first drive circuit 350, and a second drive circuit 360. The drive circuits 350 and 360 are configured to drive (i.e., excite) the LC tank 320. In the example shown in FIG. 3, the first drive circuit 350 includes transistors 352 and 354, in which the gate of the transistor 352 is coupled to the drain of the transistor 354, and the gate of the transistor 354 is coupled to the drain of the transistor 352. The sources of the transistors 352 and 354 are coupled to a supply rail. The second drive circuit 360 includes transistors 362 and 364, in which the gate of the transistor 362 is coupled to the drain of the transistor 364, and the gate of the transistor 364 is coupled to the drain of the transistor 362. The sources of the transistors 352 and 354 are coupled to ground (or some reference potential). In the example in FIG. 3, the transistors 352 and 354 are implemented with respective p-type field effect transistors (PFETs) and the transistors 362 and 364 are implemented with respective n-type field effect transistors (NFETs). However, it is to be appreciated that the transistors 352, 354, 362, and 364 are not limited to this example.

The LC tank 320 includes an inductor 330 and a voltage-controlled capacitor 340. The inductor 330 and the voltage-controlled capacitor 340 may be coupled in parallel, as shown in the example in FIG. 3. However, it is to be appreciated that the LC tank 320 is not limited to this example. In this example, the LC tank 320 outputs an LO signal at an output 375, in which the frequency of the LO signal is based on the resonant frequency of the LC tank 320.

The voltage-controlled capacitor 340 is configured to receive a control voltage (labeled “Vtune”) at an input 370 and set the capacitance of the voltage-controlled capacitor 340 based on the control voltage. The voltage-controlled capacitor 340 may include one or more varactors 342 and 344 (e.g., metal-oxide-semiconductor MOS varactors). In this example, the control voltage controls the capacitance of the voltage-controlled capacitor 340, which controls the resonance frequency of the LC tank 320, and hence controls the frequency of the LO signal output by the LC tank 320. This allows a circuit that generates the control voltage to tune the frequency of the LO signal by tuning the capacitance of the voltage-controlled capacitor 340 using the control voltage. In some implementations, the VCO 310 may be included in a PLL configured to tune (i.e., adjust) the frequency of the LO signal using the control voltage based on feedback from the output 375 and a reference clock to achieve a desired frequency for the LO signal.

In the example shown in FIG. 3, the inductor 330 has a first terminal 332 coupled to a first terminal 346 of the voltage-controlled capacitor 340, and a second terminal 334 coupled to a second terminal 348 of the voltage-controlled capacitor 340. In this example, the voltage-controlled capacitor 340 provides the tunable capacitance between the terminals 346 and 348. Also, in this example, the first terminal 332 of the inductor 330 is coupled to the drains of the transistors 352 and 362, and the second terminal 334 of the inductor 330 is coupled to the drains of the transistors 354 and 364. It is to be appreciated that a terminal may also be referred to as a port or another term.

It is to be appreciated that the VCO 310 may include one or more additional components not shown in FIG. 3. For example, in some implementations, the VCO 310 may include a switchable capacitor bank (not shown) coupled in parallel with the inductor 330. It is also to be appreciated that one of the drive circuits 350 and 360 may be omitted in some implementations.

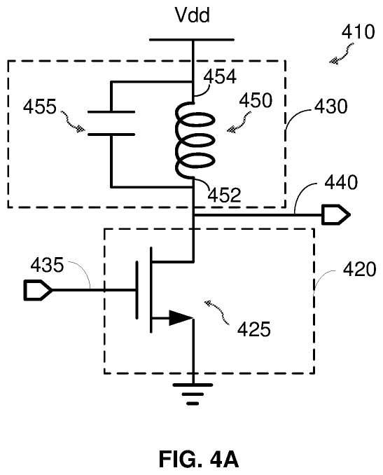

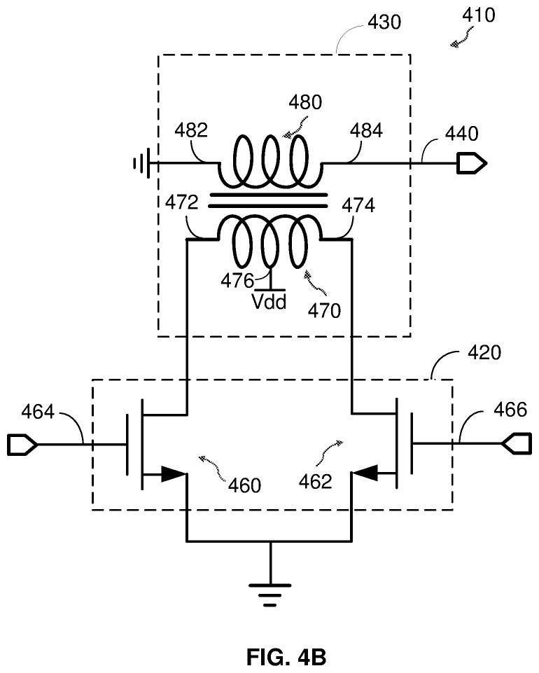

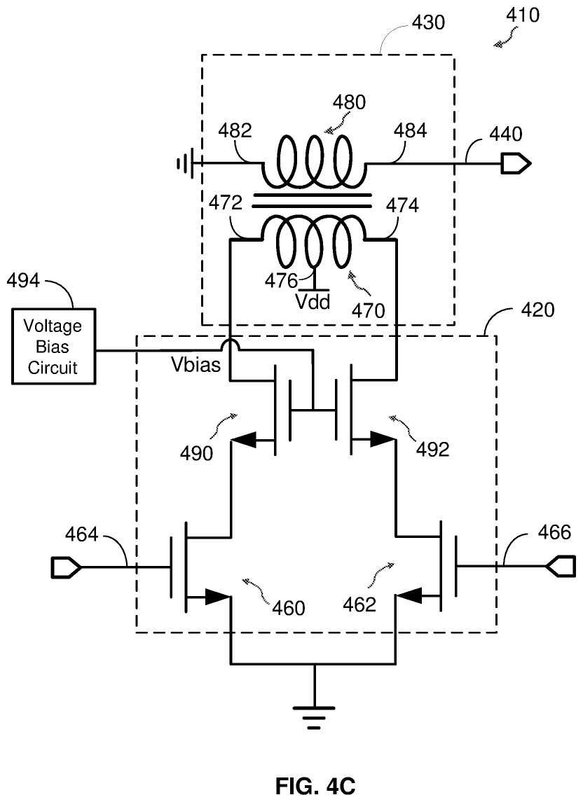

FIG. 4A shows an exemplary PA 410 according to certain aspects. The PA 410 is configured to amplify an input signal at an input 435 of the PA 410 and output the resulting amplified signal at an output 440 of the PA 410. In this example, the PA 410 includes an input circuit 420 and a load 430. Each of the PAs 210 and 244 may include a separate instance of the PA 410. However, it is to be appreciated that the PAs 210 and 244 are not limited to this example.

In the example shown in FIG. 4A, the input circuit 420 includes an input transistor 425 in which the gate of the input transistor 425 is coupled to the input 435 of the PA 410, and the source of the input transistor 425 is coupled to a ground (or some reference potential). The load 430 is coupled between the drain of the input transistor 425 and a supply rail. The output 440 of the PA 410 may be between the load 430 and the drain of the input transistor 425.

In this example, the load 410 includes an inductor 450 and a capacitor 455. The inductor 450 and the capacitor 455 may be coupled in parallel or in another configuration. In the example shown in FIG. 4A, the inductor 450 has a first terminal 452 coupled to the drain of the input transistor 425 and a second terminal 454 coupled to the supply rail. In some implementations, the inductance of the inductor 450 and/or the capacitance of the capacitor 455 may be selected to provide high gain in a desired frequency band. In some implementations, the capacitor 455 may be omitted. It is to be appreciated that the load 430 may include one or more additional components not shown in FIG. 4. For example, the load 430 may include one or more additional inductors and/or one or more additional capacitors arranged in various configurations.

It is also to be appreciated that, in some implementations, the PA 410 may be implemented as a differential PA. In this regard, FIG. 4B shows an example in which the PA 410 is implemented as a differential PA. In this example, the input circuit 420 includes a first input transistor 460 and a second input transistor 462, in which the gate of the first input transistor 460 is coupled to a first input 464, and the gate of the second input transistor 462 is coupled to a second input 466. The sources of the input transistors 460 and 462 may be coupled to a ground (or some reference potential). In this example, the PA 410 is configured to amplify a differential input signal, in which the differential input signal includes a first input signal input to the first input 464 and a second input signal input to the second input 466.

In this example, the load 430 includes a first inductor 470 and a second inductor 480 magnetically coupled to the first inductor 475. The first inductor 470 is coupled between the drain of the first input transistor 460 and the drain of the second input transistor 462. In the example shown in FIG. 4B, the first inductor 470 has a first terminal 472 coupled to the drain of the first input transistor 460 and a second terminal 474 coupled to the drain of the second input transistor 462. The second inductor 480 is coupled between a ground (or some reference potential) and an output 440. In the example shown in FIG. 4B, the second inductor 480 has a first terminal 482 coupled to the ground and a second terminal 484 coupled to the output 440. However, it is to be appreciated that the present disclosure is not limited to this example. As shown in FIG. 4B, the first inductor 470 may be coupled to the supply rail via a tap 476 (e.g., a center tap).

FIG. 4C shows another example of the PA 410 in which the PA 410 further includes a first cascode transistor 490 and a second cascode transistor 492 (e.g., to increase gain). In this example, the drain of the first cascode transistor 490 is coupled to the first terminal 472 of the inductor 470, the source of the first cascode transistor 490 is coupled to the drain of the first input transistor 460, the drain of the second cascode transistor 492 is coupled to the second terminal 474 of the inductor 470, and the source of the second cascode transistor 492 is coupled to the drain of the second input transistor 462. The gate of the first cascode transistor 490 and the gate of the second cascode transistor 492 are biased by a bias voltage Vbias. The bias voltage Vbias may be generated by a voltage bias circuit 494 coupled to the gates of the cascode transistors 490 and 492. The voltage bias circuit 494 may be implemented with a voltage divider (not shown) or another type of bias circuit. In some implementations, the voltage bias circuit 494 may be coupled to the gates of the cascode transistors 490 and 492 via a gate resistor (not shown).

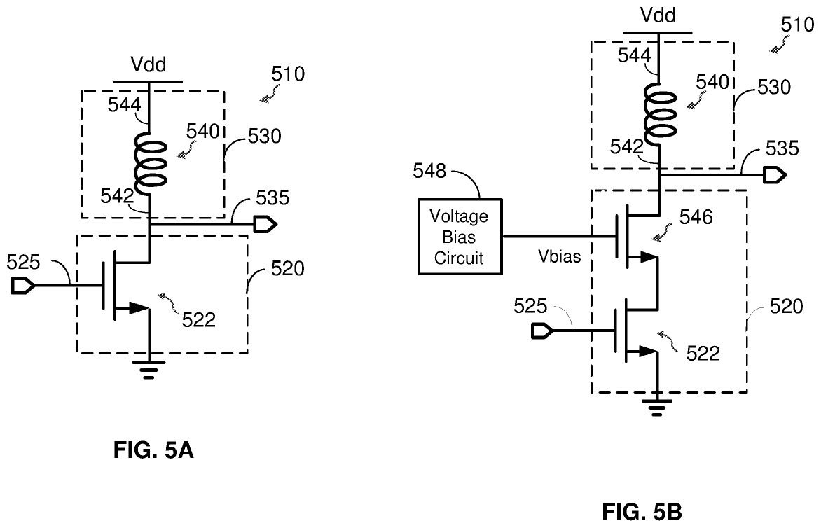

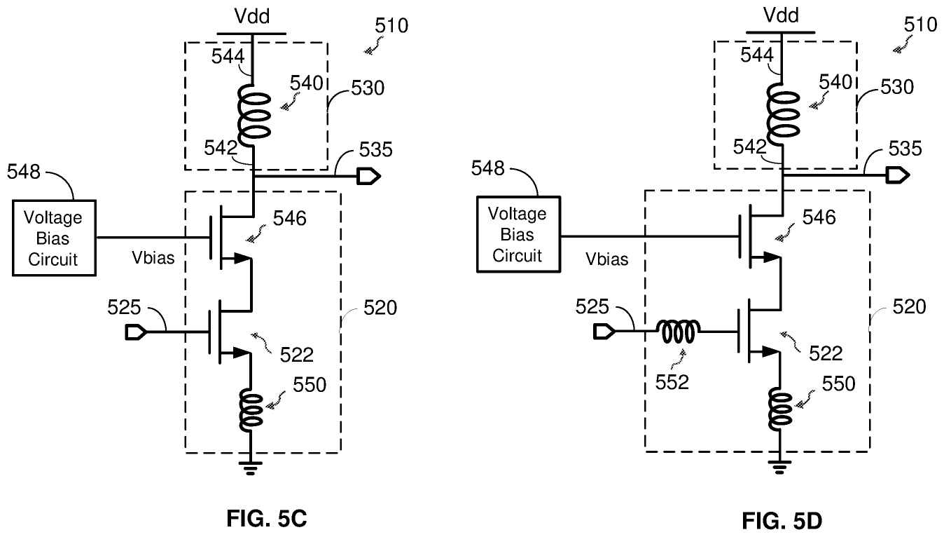

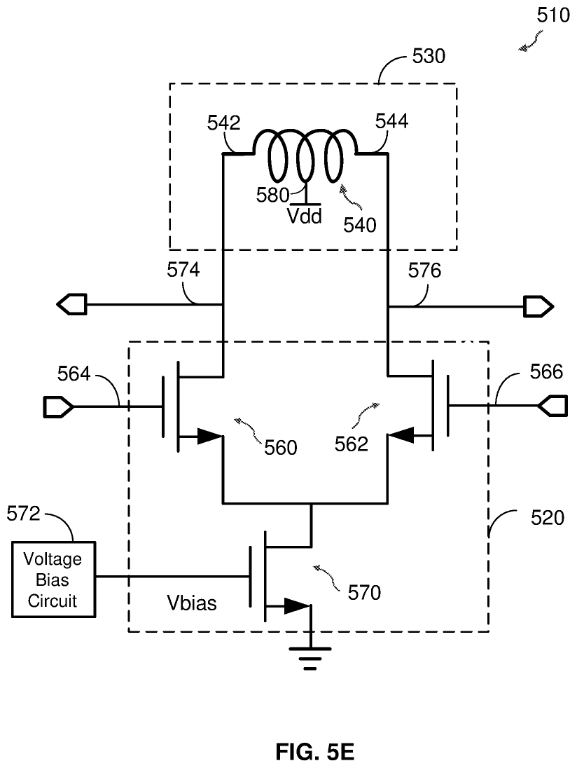

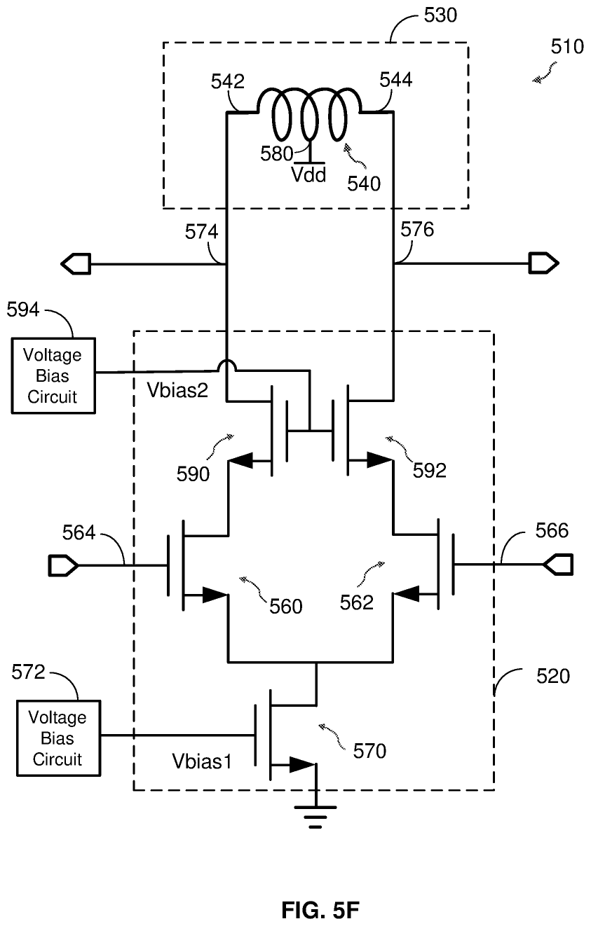

FIG. 5A shows an exemplary LNA 510 according to certain aspects. The LNA 510 is configured to amplify an input signal at an input 525 of the LNA 510 and output the resulting amplified signal at an output 535 of the LNA 510. In this example, the LNA 510 includes an input circuit 520 and a load 530. Each of the LNAs 214 and 254 may include a separate instance of the LNA 510. However, it is to be appreciated that the LNAs 214 and 254 are not limited to this example.

In the example shown in FIG. 5A, the input circuit 520 includes an input transistor 522 in which the gate of the input transistor 522 is coupled to the input 525 of the LNA 510, and the source of the input transistor 522 is coupled to a ground (or some reference potential). The load 530 is coupled between the drain of the input transistor 522 and a supply rail. The output 535 of the LNA 510 may be between the load 530 and the drain of the input transistor 522.

In this example, the load 530 includes an inductor 540 coupled between the drain of the input transistor 522 and the supply rail. The inductor 540 has a first terminal 542 coupled to the drain of the input transistor 522 and a second terminal 544 coupled to the supply rail. It is to be appreciated that that the load 530 may include one or more additional components not shown in FIG. 5A. For example, the load 530 may include one or more additional inductors and/or one or more capacitors arranged in various configurations.

It is to be appreciated that the LNA 510 may include one or more additional components not shown in FIG. 5A. For example, FIG. 5B shows an example in which the input circuit 520 further includes a cascode transistor 546 (e.g., to increase gain). In this example, the gate of the cascode transistor 546 is biased by a bias voltage Vbias, the source of the cascode transistor 546 is coupled to the drain of the input transistor 523, and the load 530 is coupled between the drain of the cascode transistor 546 and the supply rail. The bias voltage Vbias may be generated by a voltage bias circuit 548 coupled to the gate of the cascode transistor 546. The voltage bias circuit 548 may be implemented with a voltage divider (not shown) or another type of bias circuit. In the example shown in FIG. 5B, the first terminal 542 of the inductor 540 is coupled to the drain of the cascode transistor 546 and second terminal 544 of the inductor 540 is coupled to the supply rail.

FIG. 5C shows an example in which the input circuit 520 further includes a source-degeneration inductor 550 coupled between the source of the input transistor 522 and the ground (or some reference potential). FIG. 5D shows an example in which the input circuit 520 further includes a gate inductor 552 coupled between the input 525 and the gate of the input transistor 522.

It is to be appreciated that, in some implementations, the LNA 510 may be implemented as a differential LNA. In this regard, FIG. 5E shows an example in which the LNA 510 is implemented as a differential LNA. In this example, the input circuit 520 includes a first input transistor 560 and a second input transistor 562, in which the gate of the first input transistor 560 is coupled to a first input 564, and the gate of the second input transistor 562 is coupled to a second input 566.

In this example, the LNA 510 is configured to amplify a differential input signal, in which the differential input signal includes a first input signal input to the first input 564 and a second input signal input to the second input 566. In some implementations, the LNA 510 outputs a differential output signal, in which the differential output signal includes a first output signal output from a first output 574 and a second output signal output from a second output 576. The first output 574 may be coupled to the drain of the first input transistor 560 and the second output 576 may be coupled to the drain of the second input transistor 562. However, it is to be appreciated that the present disclosure is not limited to this example.

The input circuit 520 may also include a transistor 570 configured to provide a bias current for the input transistors 560 and 562. In this example, the transistor 570 is coupled between the sources of the input transistors 560 and 562 and a ground (or some reference potential), in which the gate of the transistor 570 is biased by a bias voltage Vbias. The bias voltage Vbias may be generated by a voltage bias circuit 572 coupled to the gate of the transistor 570. The voltage bias circuit 572 may be implemented with a voltage divider (not shown) or another type of bias circuit. It is to be appreciated that the source of the transistor 570 may be coupled to the ground through an inductor (not shown) in some implementations.

In this example, the inductor 540 is coupled between the drain of the second input transistor 562 and the drain of the second input transistor 562. In the example shown in FIG. 5E, the first terminal 542 of the inductor 540 is coupled to the drain of the first input transistor 560 and the second terminal 544 of the inductor 540 is coupled to the drain of the second input transistor 562. As shown in FIG. 5E, the inductor 540 may be coupled to the supply rail via a tap 580 (e.g., center tap). It is to be appreciated that the load 530 may include one or more additional components (e.g., one or more capacitors) not shown in FIG. 5E.

FIG. 5F shows another example of the LNA 510 in which the input circuit 520 further includes a first cascode transistor 590 and a second cascode transistor 592 (e.g., to increase gain). In this example, the drain of the first cascode transistor 590 is coupled to the first terminal 542 of the inductor 540, the source of the first cascode transistor 590 is coupled to the drain of the first input transistor 560, the drain of the second cascode transistor 592 is coupled to the second terminal 544 of the inductor 540, and the source of the second cascode transistor 592 is coupled to the drain of the second input transistor 562. The gate of the first cascode transistor 590 and the gate of the second cascode transistor 592 are biased by a bias voltage Vbias2. In the example shown in FIG. 5F, the first output 574 is coupled to the drain of the first cascode transistor 590 and the second output 576 is coupled to the drain of the second cascode transistor 592. However, it is to be appreciated that the present disclosure is not limited to this example.

The bias voltage Vbias2 may be generated by a voltage bias circuit 594 coupled to the gates of the cascode transistors 590 and 592. The voltage bias circuit 594 may be implemented with a voltage divider (not shown) or another type of bias circuit. In some implementations, the voltage bias circuit 594 may be coupled to the gates of the cascode transistors 590 and 592 via a gate resistor (not shown). Note that in FIG. 5F, the bias voltage applied to the gate of the transistor 570 is labeled Vbias1 to distinguish this bias voltage from the bias voltage Vbias2 applied to the gates of the cascode transistors 590 and 592.

Thus, various components in the transceiver 196 may include inductors such as the PAs 210 and 244, the LNAs 214 and 254, the frequency synthesizers 224, 232, 240, and 250, and/or antenna couplers 206 and 208. A challenge with using inductors in the transceiver 196 is that there is unwanted magnetic coupling between inductors in the various components of the transceiver 196, which degrades the performance of the transceiver 196. For example, unwanted magnetic coupling in the transceiver 196 may cause frequency pulling of one or more VCOs (e.g., one or more instances of the VCO 310) in the transceiver 196, increased interference at the LNAs 214 and 254, interference between channels, etc. The unwanted magnetic coupling may worsen as components in the transceiver 196 scale down and/or are more closely spaced together. In addition, the unwanted magnetic coupling may be more of an issue as the number of simultaneously active transceiver paths increases (e.g., due to an increase in the number of bands used including additional Tx/Rx frequency division duplex (FDD) bands, additional carrier aggregation band combinations, dual subscriber scenarios, and the like).

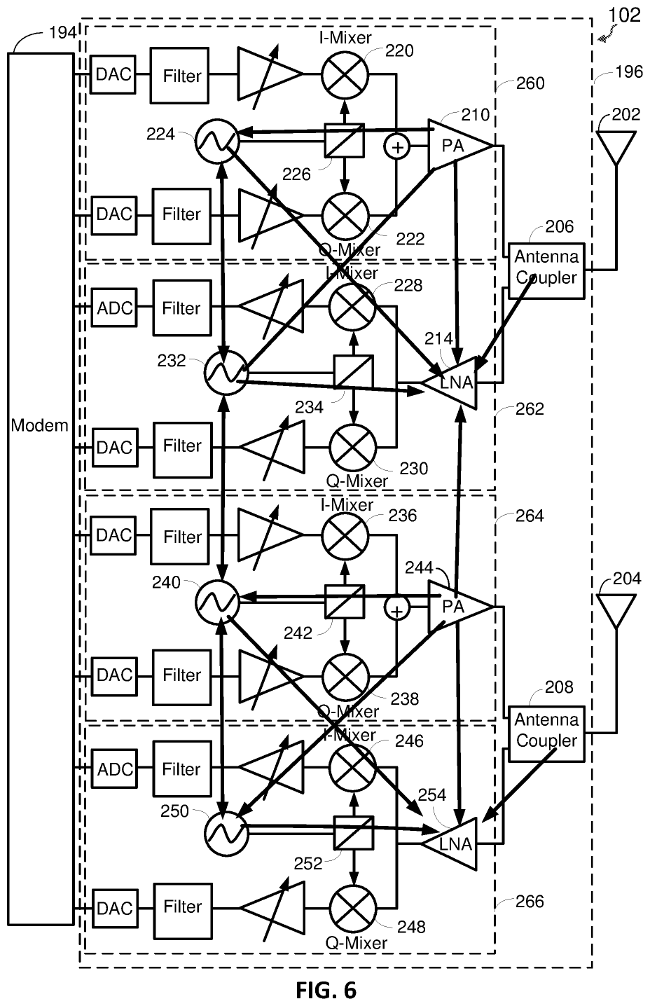

FIG. 6 shows an example of unwanted magnetic coupling between the various components in the transceiver 196 according to certain aspects. In FIG. 6, unwanted magnetic coupling is illustrated by thick arrows, in which each arrow represents unwanted magnetic coupling between a respective pair of components in the transceiver 196. For a pair of components, one of the components may act as an aggressor and the other one of the components may act as a victim in which the respective arrow points from the aggressor to the victim. The aggressor (e.g., PA 210 of 244) may operate at a higher power than the victim (e.g., the first LNA 214 or the second LNA 254), in which unwanted magnetic coupling from the aggressor to the victim negatively impacts the performance of the victim. In certain aspects, the victim may be sensitive to interference from the aggressor through the magnetic coupling. It is to be appreciated that a component that acts as a victim of a first component may also act as an aggressor to a second component. It is also to be appreciated that two components may acts as aggressors to each other.

FIG. 6 shows examples of aggressor-victim pairs in the transceiver 196. For example, one aggressor-victim pair includes the first PA 210 and the first LNA 214 in which the first PA 210 acts as the aggressor to the first LNA 214. In this example, the first PA 210 may cause interference at the first LNA 214 through magnetic coupling from the first PA 210 to the first LNA 214. Another aggressor-victim pair includes the first PA 210 and the first frequency synthesizer 224. In this example, the first PA 210 may pull the frequency of a VCO (e.g., VCO) in the first frequency synthesizer 224 through magnetic coupling. In this example, the frequency pulling may cause compression or expansion of the frequency of the first LO, which can lead to non-linearity and phase noise. Therefore, improved magnetic isolation between components in the transceiver 196 is desirable.

To address this, aspects of the present disclose provide inductor structures that substantially reduce unwanted magnetic coupling between components in a transceiver, as discussed further below.

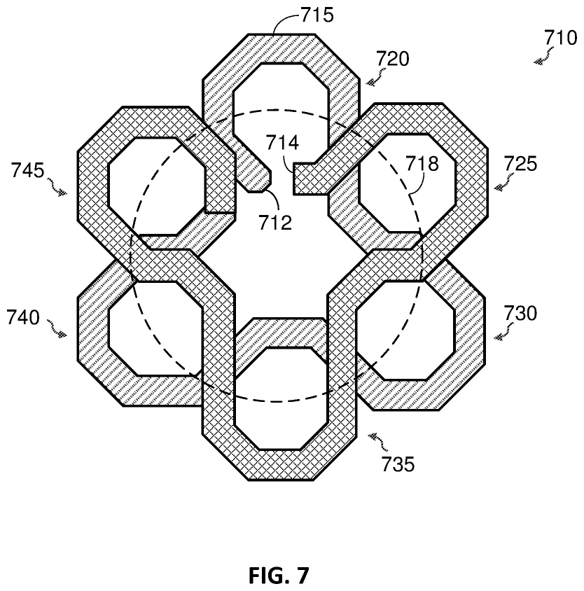

FIG. 7 shows an example of an inductor structure 710 according to certain aspects of the present disclosure. As discussed further below, the inductor structure 710 has concentrated magnetic fields that quickly diminish outside of the inductor structure 710. This feature makes the inductor structure suitable for use in an aggressor (e.g., a PA or VCO) to reduce unwanted magnetic coupling from the aggressor to a victim (e.g., an LNA or a VCO) although the inductor structure may also be suitable for use in either an aggressor or a victim. The above features and other features of the inductor structure 710 are discussed further below.

The inductor structure 710 has a first terminal 712 (also referred to as a first port) and a second terminal 714 (also referred to as a second port). The inductor structure 710 includes a conductor path 715 between the first terminal 712 and the second terminal 714. The conductor path 715 includes a first inductor 720, a second inductor 725, a third inductor 730, a fourth inductor 735, a fifth inductor 740, and a sixth inductor 745. In the example shown in FIG. 7, the inductors 720, 725, 730, 735, 740, and 745 are arranged along a ring 718 (i.e., a circle) according to certain aspects. Although six inductors are shown in the example in FIG. 7, it is to be appreciated that the inductor structure 710 is not limited to six inductors. For example, in some implementations, the conductor path 715 may include eight or more inductors arranged along the ring 718.

Each of the inductors 720, 725, 730, 735, 740, and 745 may have a loop shape or another shape. An inductor having a loop shape may also be referred to as a loop inductor or another term. It is to be appreciated that a loop of a loop inductor may be an open loop (also referred to as a lobe) having a gap or an opening separating two ends of the inductor. A loop inductor having an open loop may also be referred to as a lobe inductor. A loop inductor may have any one of various shapes including a U shape, a hexagonal shape, an octagonal shape, or another shape. In some implementations, each of the inductors 720, 725, 730, 735, 740, and 745 is a planar inductor (e.g., a planar loop inductor). As used herein, a planar inductor is an inductor formed from a flat metal layer, which may be on and/or embedded in a substrate (e.g., silicon substrate, laminate, ceramic, PCB, etc.). It is also to be appreciated that each of the inductors 720, 725, 730, 735, 740, and 745 may have a single turn or multiple turns.

In the example shown in FIG. 7, the first inductor 720 and the second inductor 725 are adjacent to each other, the third inductor 730 and the fourth inductor 735 are adjacent to each other, and the fifth inductor 740 and the sixth inductor 745 are adjacent to each other. It is to be appreciated that the first inductor 720 may also be also adjacent to the sixth inductor 745, the second inductor 725 may also be adjacent to the third inductor 730, and the fourth inductor 735 may also be adjacent to the fifth inductor 740, as shown in the example in FIG. 7.

When the inductor structure 710 is driven by a circuit (e.g., an input circuit of a PA, a drive circuit of a VCO, etc.) coupled to the first terminal 712 and/or the second terminal 714, current flows through the conductor path 715 from the first terminal 712 to the second terminal 714 or from the second terminal 714 to the first terminal 712.

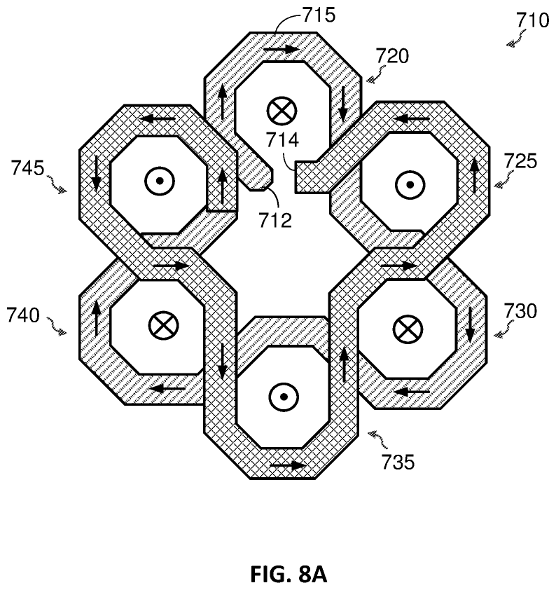

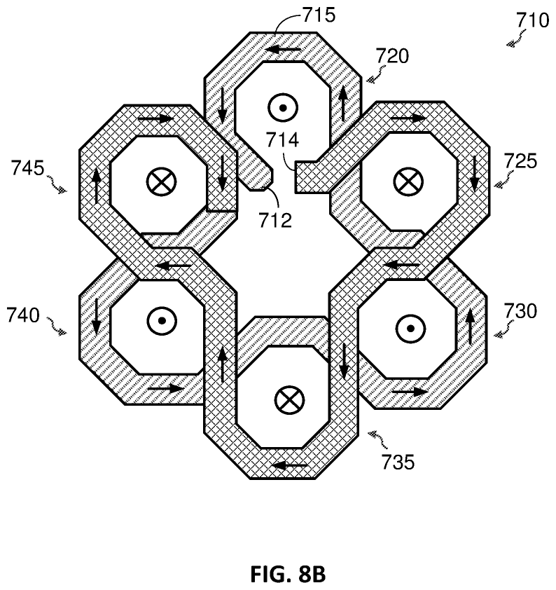

In this example, the conductor path 715 is configured such that, when current flows from the first terminal 712 to the second terminal 714, the current flows in a first direction (e.g., clockwise direction) in the first inductor 720, the third inductor 730, and the fifth inductor 740, and the current flows in a second direction (e.g., counterclockwise direction) in the second inductor 725, the fourth inductor 735, and the sixth inductor 745, where the first direction and the second direction are opposite. Since the first inductor 720, the third inductor 730, and the fifth inductor 740 are adjacent to the second inductor 725, the fourth inductor 735, and the sixth inductor 745, respectively, this causes the current to flow in opposite directions in the inductors of each pair of adjacent inductors (e.g., the adjacent inductors 720 and 725, the adjacent inductors 730 and 735, and the adjacent inductors 740 and 745). In this regard, FIG. 8A illustrates an example of the current flow in the conductor path 715 of the inductor structure 710 for the case where current enters the first terminal 712 (i.e., current flows from the first terminal 712 to the second terminal 714). In FIG. 8A, the direction of the current flow is indicated by arrows. As shown in FIG. 8A, the current flows in the clockwise direction in the first inductor 720, the third inductor 730, and the fifth inductor 740, and the current flows in counterclockwise direction in the second inductor 725, the fourth inductor 735, and the sixth inductor 745.

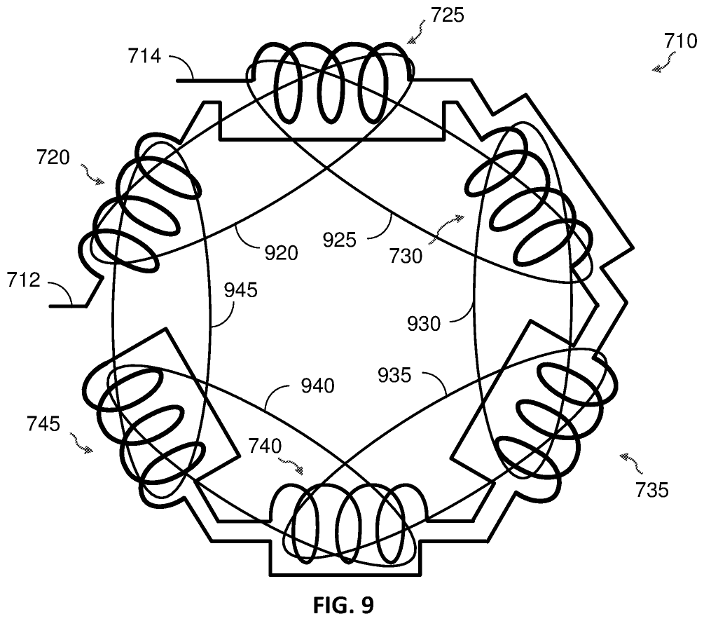

The opposite flow of current in the inductors of each pair of adjacent inductors causes the magnetic fields in the inductors of each pair of adjacent inductors to have opposite polarity (i.e., direction). This forms magnetic field loops through each pair of adjacent inductors, as discussed further below with reference to FIG. 9.

FIG. 8B shows an example of the current flow in the conductor path 715 of the inductor structure 710 for the case where the current enters the second terminal 714 (i.e., the current flows from the second terminal 714 to the first terminal 712). As shown in FIG. 8B, the current flows in opposite directions in the inductors of each pair of adjacent inductors (e.g., the adjacent inductors 720 and 725, the adjacent inductors 730 and 735, and the adjacent inductors 740 and 745). As a result, the magnetic fields in the inductors of each pair of adjacent inductors have opposite polarity (i.e., direction).

Thus, the magnetic fields in the inductors of each pair of adjacent inductors have opposite polarity (i.e., direction) for both the case where current enters the first terminal 712 and the case where current enters the second terminal 714. This causes strong magnetic coupling between the inductors of each pair of adjacent inductors. An example of the strong magnetic coupling is illustrated in FIG. 9, which shows a circuit schematic representation of the inductor structure 710. FIG. 9 shows strong magnetic field loops 905, 910, 920, 925, 930, and 935 running through the inductors of each pair of adjacent inductors. Because of the strong magnetic coupling between the inductors of each pair of adjacent inductors, the magnetic fields of the inductor structure 710 are concentrated around the ring 718 of the inductor structure 710 and quickly diminish outside of the inductor structure 710.

In other words, the inductor structure 710 includes multiple inductor dipole pairs along the ring 718 which help concentrate the magnetic fields of the inductor structure 710 around the ring 718. Each inductor dipole pair includes two adjacent inductors having opposite magnetic field polarity due to opposite current flow in the two adjacent inductors. In the example shown in FIG. 7, the inductor structure 710 includes three inductor dipole pairs (e.g., the inductors 720 and 725, the inductors 730 and 735, and the inductors 740 and 745). However, it is to be appreciated that the present disclosure is not limited to this example. For example, in other implementations, the inductor structure 710 may include four inductor dipole pairs. As used herein, an inductor dipole pair includes a pair of inductors having opposite magnetic field polarities. For the example of an inductor dipole pair including a pair of loop inductors (e.g., lobe inductors), the current flowing through the inductor dipole pair flows in the clockwise direction in one of the loop inductors of the dipole pair and flows in the counterclockwise direction in the other one of the loop inductors of the dipole pair.

The quickly diminishing magnetic fields outside of the inductor structure 710 makes the inductor structure 710 desirable for used in an aggressor to reduce unwanted magnetic coupling from the aggressor to a victim. For example, as discussed further below, the inductor structure 710 may be used to implement an inductor coupled between the drains of the input transistors (e.g., input transistors 460 and 465) of a differential PA (e.g., PA 410), and/or an inductor in the LC tank (e.g., LC tank 320) of a VCO (e.g., VCO 310).

In addition, in the example illustrated in FIGS. 7, 8A, 8B, and 9, the magnetic field in the center of the inductor structure 710 is approximately zero. This allows one or more active devices to be placed at or near the center of the inductor structure 710 for a more compact design, as discussed further below.

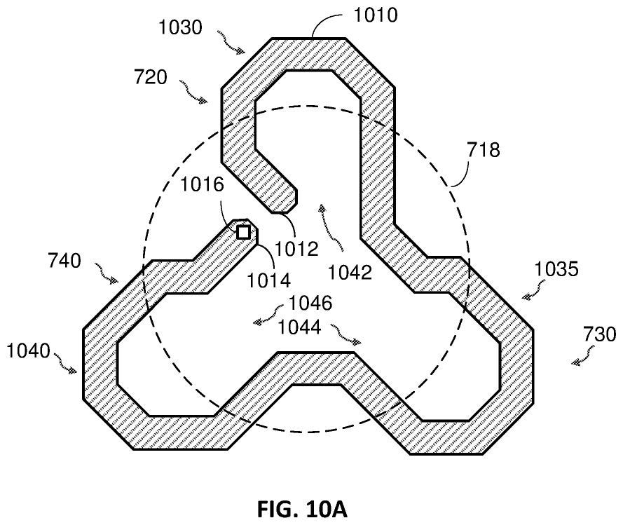

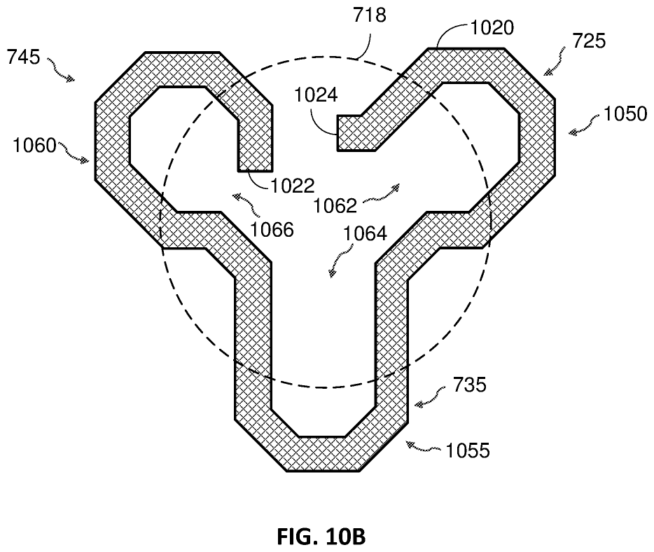

In certain aspects, the conductor path 715 of the inductor structure 710 is formed from two or more metal layers. The metal layers may be metal layers in a chip (i.e., die), metal layers in a substrate (e.g., a laminate, a PCB, etc.), and the like. In this regard, FIG. 10A shows an example of a first portion 1010 of the conductor path 715 and FIG. 10B shows an example of a second portion 1020 of the conductor path 715. The first portion 1010 may also be referred to as a first conductor path, and the second portion 1020 may also be referred to as a second conductor path where the conductor path 715 includes the first and second conductor paths. Note that FIGS. 10A and 10B show the first portion 1010 and the second portion 1020 of the conductor path 715 separately for ease of illustration.

In certain aspects, the first portion 1010 is formed from a first metal layer (e.g., using a lithographic and etching process). In this example, the first portion 1010 is contiguous in the first metal layer, and is patterned to form a first loop portion 1030, a third loop portion 1035, and a fifth loop portion 1040 corresponding to the first inductor 720, the third inductor 730, and the fifth inductor 740, respectively. The second portion 1020 is formed from a second metal layer different from the first metal layer (e.g., using a lithographic and etching process). In this example, the second portion 1020 is contiguous in the second metal layer, and is patterned to form a second loop portion 1050, a fourth loop portion 1055, and a sixth loop portion 1060 corresponding to the second inductor 725, the fourth inductor 735, and the sixth inductor 745, respectively. As shown in FIGS. 10A and 10B, the first loop portion 1030, the second loop portion 1050, the third loop portion 1035, the fourth loop portion 1055, the fifth loop portion 1040, and the sixth loop portion 1060 are positioned in a circular arrangement such that a circumference of the ring 718 (i.e., circle) passes through each of the first loop portion 1030, the second loop portion 1050, the third loop portion 1035, the fourth loop portion 1055, the fifth loop portion 1040, and the sixth loop portion 1060.

In some implementations, the second metal layer is above the first metal layer, which allows the second portion 1020 of the conductor path 715 to pass over the first portion 1010 of the conductor path 715. In other implementations, the second metal layer is below the first metal layer, which allows the second portion 1020 of the conductor path 715 to pass under the first portion 1010 of the conductor path 715. The first and second metal layers may be metal layers in a chip (i.e., a die), metal layers in a substrate (e.g., a laminate, a PCB, etc.), and the like.

The first portion 1010 of the conductor path 715 has a first end 1012 and a second end 1014. The first end 1012 corresponds to the first terminal 712 shown in FIG. 7. In this example, the first loop portion 1030 partially encloses a first area 1042, the third loop portion 1035 partially encloses a third area 1044, and the fifth loop portion 1040 partially encloses a fifth area 1046. Current flow through the first portion 1010 causes the first loop portion 1030 to generate a magnetic field in the first area 1042, causes the third loop portion 1035 to generate a magnetic field in the third area 1044, and causes the fifth loop portion 1040 to generate a magnetic field in the fifth area 1046.

For the case where current enters the first terminal 712, the current flows from the first end 1012 to the second end 1014 of the first portion 1010 of the conductor path 715 in the first direction (e.g., clockwise direction). In this case, the current flow through the first loop portion 1030, the third loop portion 1035, and the fifth loop portion 1040 generates magnetic fields in the first area 1042, the third area 1044, and the fifth area 1046 with the polarity shown in the example in FIG. 8A. It is to be appreciated that current may also flow in the opposite direction (e.g., depending on the polarity of the signal driving the inductor structure 710).

Referring to FIG. 10B, the second portion 1020 of the conductor path 715 has a first end 1022 and a second end 1024. The second end 1024 corresponds to the second terminal 714 shown in FIG. 7. As discussed further below, the first end 1022 is coupled to the second end 1014 of the first portion 1010 (e.g., by one or more vias 1016 disposed between the first metal layer and the second metal layer). In this example, the second loop portion 1050 partially encloses a second area 1062, the fourth loop portion 1055 partially encloses a fourth area 1064, and the sixth loop portion 1060 partially encloses a sixth area 1066. Current flow through the second portion 1020 causes the second loop portion 1050 to generate a magnetic field in the second area 1062, causes the fourth loop portion 1055 to generate a magnetic field in the fourth area 1064, and causes the sixth loop portion 1060 to generate a magnetic field in the sixth area 1066.

For the case where current enters the first end 1022 of the second portion 1020 from the second end 1014 of the first portion 1010, the current flows from the first end 1022 to the second end 1024 of the second portion 1020 of the conductor path 715 in the second direction (e.g., counterclockwise direction). In this case, the current flow through the second loop portion 1050, the fourth loop portion 1055, and the sixth loop portion 1060 generates magnetic fields in the second area 1062, the fourth area 1064, and the sixth area 1066 with the polarity shown in the example in FIG. 8A. It is to be appreciated that current may also flow in the opposite direction (e.g., depending on the polarity of the signal driving the inductor structure 710).

For the example where the current enters the first terminal 712, the current flows through the first portion 1010 of the conductor path 715 in the first direction (e.g., clockwise direction). The current then flows from the second end 1014 of the first portion 1010 of the conductor path 715 to the first end 1022 of the second portion 1020 of the conductor path 715 (e.g., through the one or more vias 1016). The current then flows from the first end 1022 to the second end 1024 of the second portion 1020 in the second direction (e.g., counterclockwise direction). Thus, in this example, the current changes direction from the first direction (e.g., clockwise direction) in the first portion 1010 of the conductor path 715 to the second direction (e.g., counterclockwise direction) in the second portion 1020 of the conductor path 715. Thus, the first loop portion 1030, the second loop portion 1050, the third loop portion 1035, the fourth loop portion 1055, the fifth loop portion 1040, and the sixth loop portion 1060 are coupled such that when a current flows from the first terminal 712 to the second terminal 714, the current flows in the first direction (e.g., clockwise) in the first loop portion 1030, the third loop portion 1035, and the fifth loop portion 1040, and the current flows in the second direction (e.g., counterclockwise) in the second loop portion 1050, the fourth loop portion 1055, and the sixth loop portion 1060.

The first portion 1010 and the second portion 1020 of the conductor path 715 are discussed above for the case where current enters the first terminal 712 of the inductor structure 710. For the case where current enters the second terminal 714 of the inductor structure 710, the current flows through the second portion 1020 of the conductor path 715 in the first direction (e.g., clockwise direction), and flows through the first portion 1010 of the conductor path 715 in the second direction (e.g., counterclockwise direction). In both cases, the current changes direction (e.g., from clockwise to counterclockwise or vice versa) between the first portion 1010 and the second portion 1020 of the inductor structure 710.

Although two metal layers are shown in the example in FIGS. 10A and 10B, it is to be appreciated that the inductor structure 710 may include one or more additional metal layers not shown in FIGS. 10A and 10B. For example, in some implementations, the inductor structure 710 may include four metal layers or six metal layers, In this example, the four metal layers or the six metal layers may include odd metal layers and even metal layers, in which the direction of current flow in the odd metal layers and the direction of current flow in the even metal layers are opposite. For instance, the direction of current flow in the odd metal layers may be counterclockwise and the direction of current flow in the even metal layers may be clockwise, or the direction of current flow in the odd metal layers may be clockwise and the direction of current flow in the even metal layers may be counterclockwise. In this example, the inductor structure may include vias where each via couples an odd metal layer to an adjacent even metal layer, or an even metal layer to an adjacent odd metal layer. It is also to be appreciated that an inductor structure may include two or more instances of the inductor structure 710 coupled in series and/or parallel, in which the two or more instances of the inductor structure 710 may be formed in the same metal layers or different metal layers.

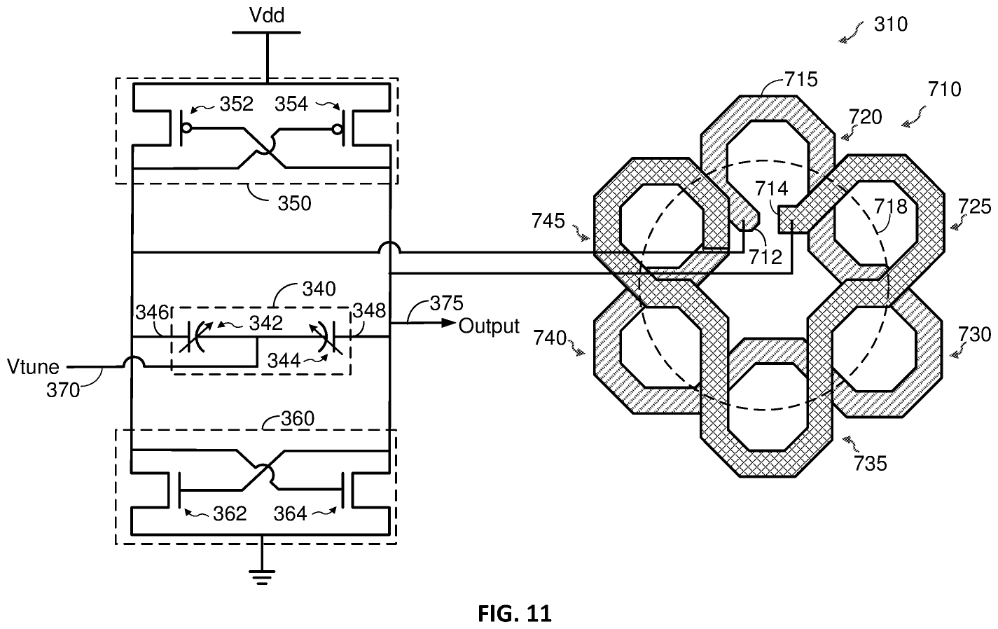

As discussed above, the quickly diminishing magnetic fields of the inductor structure 710 outside of the inductor structure 710 makes the inductor structure desirable for used in an aggressor to reduce unwanted magnetic coupling from the aggressor to a victim. In this regard, FIG. 11 shows an example in which the inductor structure 710 is used to implement the inductor 330 in the exemplary VCO 310 to reduce magnetic coupling from the VCO 310 to a victim (e.g., an LNA, a PA, etc.). The VCO 310 may be included in one of the frequency synthesizers 224, 232, 240, and 250 shown in FIG. 2.

In this example, the first terminal 712 of the inductor structure 710 is coupled to the first terminal 346 of the voltage-controlled capacitor 340 and the drains of the transistors 352 and 362. The second terminal 714 of the inductor structure 710 is coupled to the second terminal 348 of the voltage-controlled capacitor 340 and the drains of the transistors 354 and 364. It is to be appreciated that the transistors 352, 354, 362, and 364 are not drawn to scale relative to the inductor structure 710, and that the transistors 352, 354, 362, and 364 may be much smaller than the inductor structure 710. It is also to be appreciated that the VCO 310 may include one or more additional components (e.g., switchable capacitor bank) in some implementations.

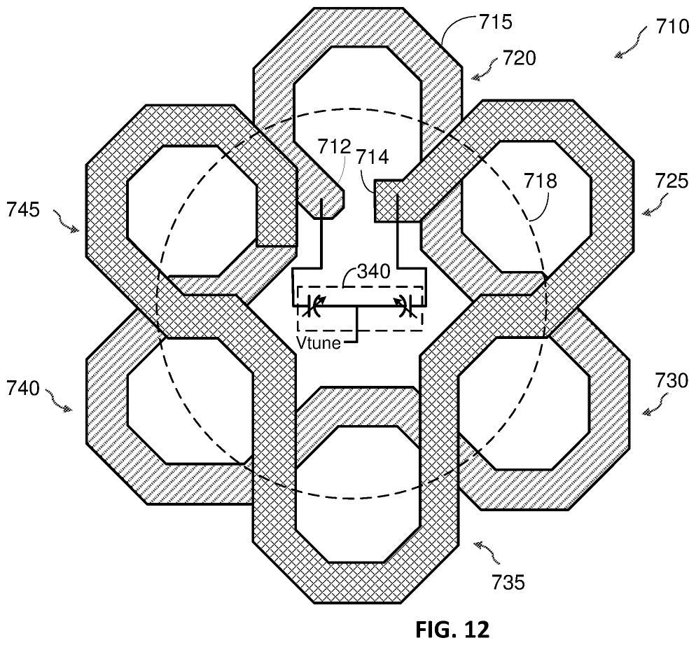

In some implementations, the transistors 352, 354, 362, and 364 and the voltage-controlled capacitor 340 may be located outside of the inductor structure 710. In other implementations, the transistors 352, 354, 362, and 364 and/or the voltage-controlled capacitor 340 may be located within the inductor structure 710 for a more compact design. For example, as discussed above, the magnetic field in the center of the inductor structure 710 may be approximately zero. This allows the transistors 352, 354, 362, and 364 and/or the voltage-controlled capacitor 340 to be located at or near the center of the inductor structure 710. In this regard, FIG. 12 shows an example where the voltage-controlled capacitor 340 is located within an area surrounded by the inductors 720, 725, 730, 735, 740, and 745. Although not shown in FIG. 12, it is to be appreciated that the transistors 352, 354, 362, and 364 may also be located within the area surrounded by the inductors 720, 725, 730, 735, 740, and 745 in some implementations.

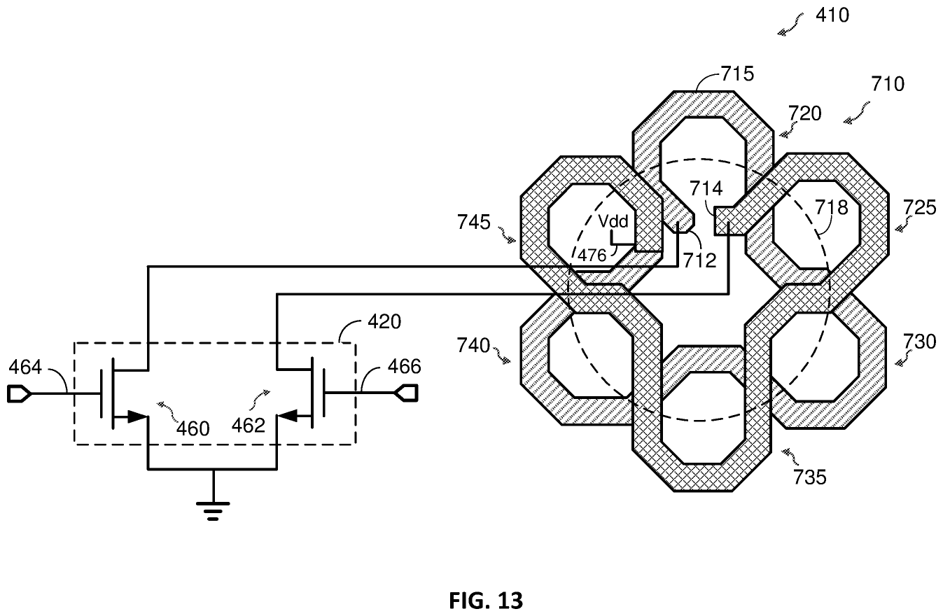

FIG. 13 shows an example in which the inductor structure 710 is used to implement the first inductor 470 in the exemplary PA 410 to reduce magnetic coupling from the PA 410 to a victim (e.g., an LNA, a VCO, etc.).

In this example, the first terminal 712 of the inductor structure 710 is coupled to the drain of the first input transistor 460, and the second terminal 714 of the inductor structure 710 is coupled to the drain of the second input transistor 462. Also, in this example, the inductor structure 710 is coupled to the supply rail via the tap 476 (e.g., center tap). In the example shown in FIG. 13, the first inductor 720, the third inductor 730, and the fifth inductor 740 are between the first terminal 712 and the tap 476, and the second inductor 725, the fourth 735, and the sixth inductor 745 are between the tap 476 and the second terminal 714. It is to be appreciated that the input transistors 460 and 462 are not drawn to scale relative to the inductor structure 710, and that the input transistors 460 and 462 may be much smaller than the inductor structure 710. It is also to be appreciated that the PA 410 may include one or more additional components (e.g., one or more capacitors) in some implementations.

In some implementations, the inductor structure 710 may be magnetically coupled with the second inductor 480 (not shown in FIG. 13). However, it is to be appreciated that the present disclosure is not limited to this example. For example, in other implementations, the PA 410 may have a first output coupled to the drain of the first input transistor 460 and a second output coupled to the drain of the second input transistor 462.

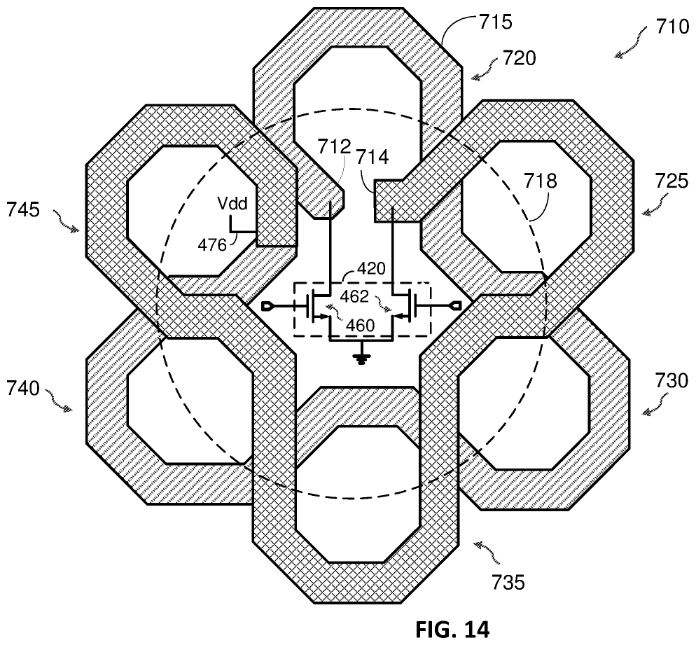

In some implementations, the input transistors 460 and 462 may be located outside of the inductor structure 710. In other implementations, the input transistors 460 and 462 may be located within the inductor structure 710 for a more compact design. For example, as discussed above, the magnetic field in the center of the inductor structure 710 may be approximately zero. This allows the input transistors 460 and 462 to be located at or near the center of the inductor structure 710. In this regard, FIG. 14 shows an example where the input transistors 460 and 462 are located within an area surrounded by the inductors 720, 725, 730, 735, 740, and 745.

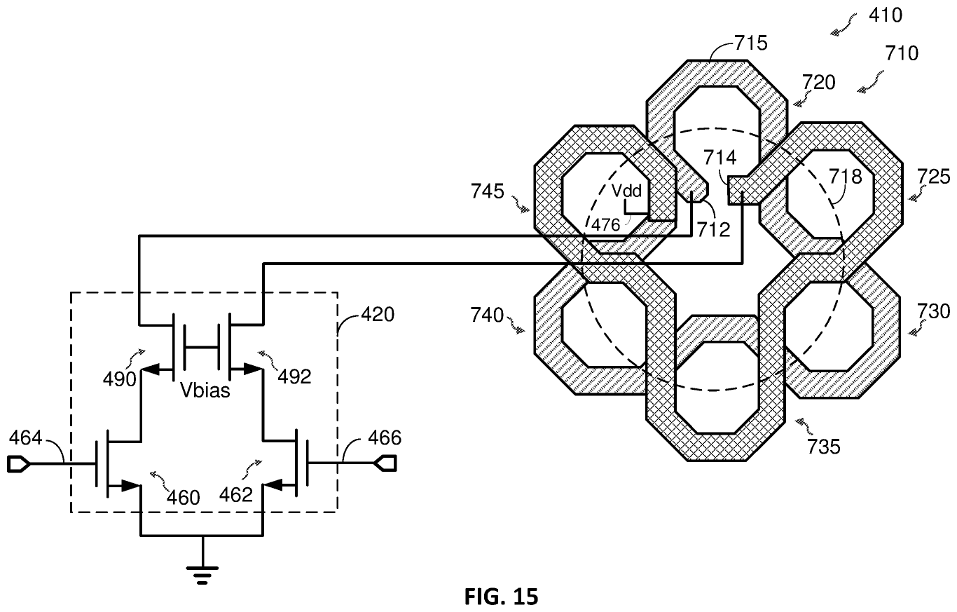

FIG. 15 shows an example where the PA 410 includes the first cascode transistor 490 and the second cascode transistor 492. In this example, the first terminal 712 of the inductor structure 710 is coupled to the drain of the first cascode transistor 490, and the second terminal 714 of the inductor structure 710 is coupled to the drain of the second cascode transistor 492.

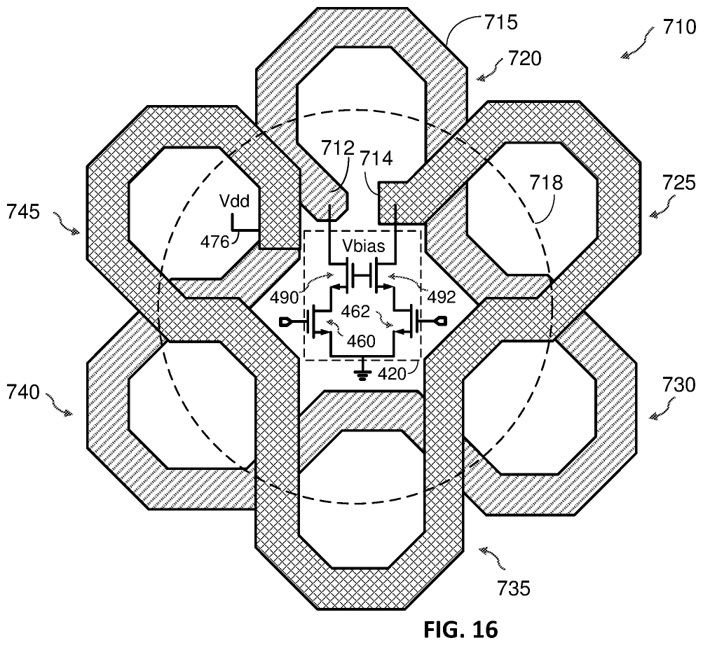

In some implementations, the input transistors 460 and 462 and the cascode transistors 490 and 492 may be located outside of the inductor structure 710. In other implementations, the input transistors 460 and 462 and the cascode transistors 490 and 492 may be located within the inductor structure 710 for a more compact design. In this regard, FIG. 16 shows an example where the input transistors 460 and 462 and the cascode transistors 490 and 492 are located within an area surrounded by the inductors 720, 725, 730. 735, 740, and 745.

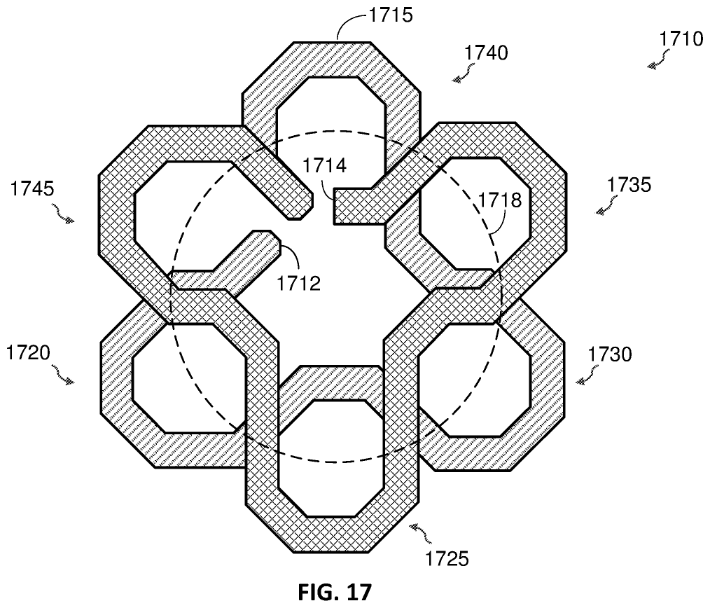

FIG. 17 shows another example of an inductor structure 1710 according to certain aspects of the present disclosure. As discussed further below, the inductor structure 1710 may be used to implement an inductor in a victim (e.g., an LNA) to provide the victim with high rejection of common mode magnetic field interference from an aggressor (although the inductor structure may be used in an aggressor in some aspects). In certain aspects, the exemplary inductor structure 1710 may be used in conjunction with the exemplary inductor structure 710 to further reduce unwanted magnetic coupling from the aggressor to the victim. In these aspects, the inductor structure 710 may be used in the aggressor (e.g., a PA or VCO) and the inductor structure 1710 may be used in the victim (e.g., an LNA or a VCO). The above features and other features of the inductor structure 1710 are discussed further below.

The inductor structure 1710 has a first terminal 1712 (also referred to as a first port) and a second terminal 1714 (also referred to as a second port). The inductor structure 1710 includes a conductor path 1715 between the first terminal 1712 and the second terminal 1714. The conductor path 1715 includes a first inductor 1720, a second inductor 1725, a third inductor 1730, a fourth inductor 1735, a fifth inductor 1740, and a sixth inductor 1745. The inductors 1720, 1725, 1730, 1735, 1740, and 1745 may be arranged along a ring 1718 (i.e., a circle) according to certain aspects. Although six inductors are shown in the example in FIG. 17, it is to be appreciated that the inductor structure 1710 is not limited to six inductors. For example, in some implementations, the conductor path 1715 may include eight inductors arranged along the ring 1718.

Each of the inductors 1720, 1725, 1730, 1735, 1740, and 1745 may have a loop shape or another shape. An inductor having a loop shape may also be referred to as a loop inductor or another term. It is to be appreciated that a loop of a loop inductor may be an open loop (also referred to as a lobe) having a gap or an opening separating two ends of the inductor. A loop inductor having an open loop may also be referred to as a lobe inductor. A loop inductor may have any one of various shapes including a U shape, a hexagonal shape, an octagonal shape, or another shape. In some implementations, each of the inductors 1720, 1725, 1730, 1735, 1740, and 1745 is a planar inductor. It is also to be appreciated that each of the inductors 1720, 1725, 1730, 1735, 1740, and 1745 may have a single turn or multiple turns.

When the inductor structure 1710 is driven by a circuit (e.g., an input circuit of an LNA) coupled to the first terminal 1712 and/or the second terminal 1714, current flows through the conductor path 1715 from the first terminal 1712 to the second terminal 1714 or from the second terminal 1714 to the first terminal 1712 (e.g., depending on the polarity of the signal from the circuit driving the inductor structure).

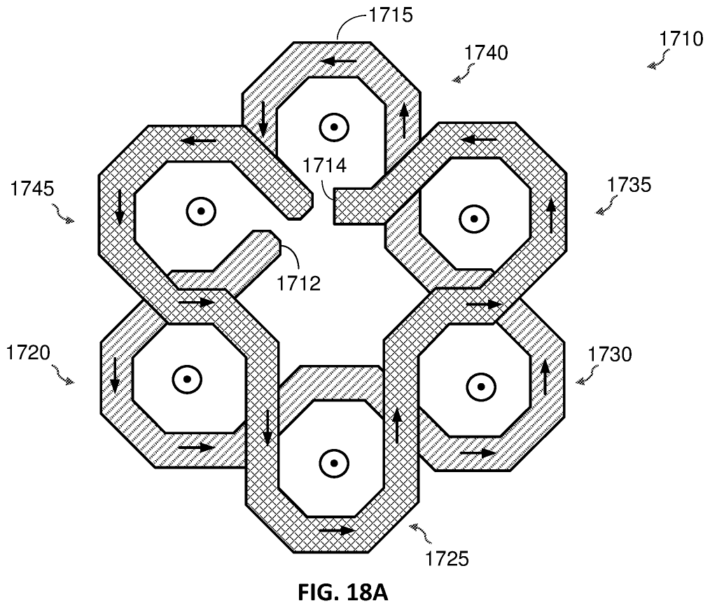

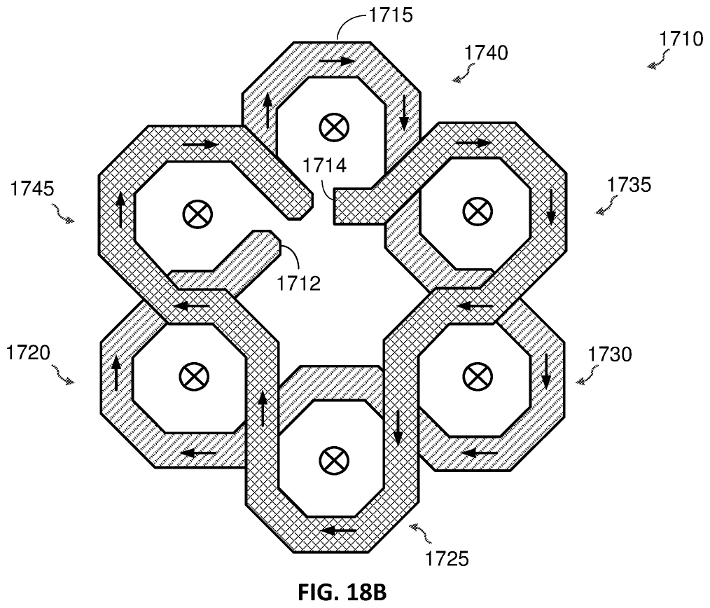

In this example, the conductor path 1715 is configured such that, when current flows from the first terminal 1712 to the second terminal 1714, the current flows in the same direction in the inductors 1720, 1725, 1730, 1735, 1740, and 1745 of the inductor structure 1710. In this regard, FIG. 18A illustrates an example of the current flow in the conductor path 1715 of the inductor structure 1710 for the case where current enters the first terminal 1712 (i.e., the current flows from the first terminal 1712 to the second terminal 1714). In FIG. 18A, the direction of the current flow is indicated by arrows. As shown in FIG. 18A, the current flows in the counterclockwise direction in the inductors 1720, 1725, 1730, 1735, 1740, and 1745. As a result, the magnetic field direction is the same through the inductors 1720, 1725, 1730, 1735, 1740, and 1745.

FIG. 18B illustrates an example of current flow in the conductor path 1715 of the inductor structure 1710 for the case where current enters the second terminal 1714 (i.e., the current flows from the second terminal 1714 to the first terminal 1712). In FIG. 18B, the direction of the current flow is indicated by arrows. As shown in FIG. 18B, the current flows in the clockwise direction in the inductors 1720, 1725, 1730, 1735, 1740, and 1745. As a result, the magnetic field direction is the same through the inductors 1720, 1725, 1730, 1735, 1740, and 1745.

Thus, magnetic field direction is the same through the inductors 1720, 1725, 1730, 1735, 1740, and 1745 of the inductor structure 710 for both the case where current enters the first terminal 1712 and the case where current enters the second terminal 1714. In other words, the polarity (i.e., direction) of magnetic fields in the inductors 1720, 1725, 1730, 1735, 1740, and 1745 is the same. As discussed further below, this property allows the inductor structure 1710 to provide rejection of common mode magnetic field interference.

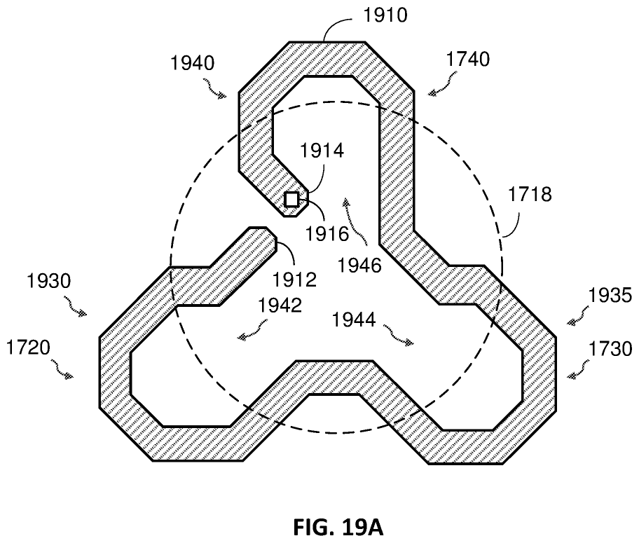

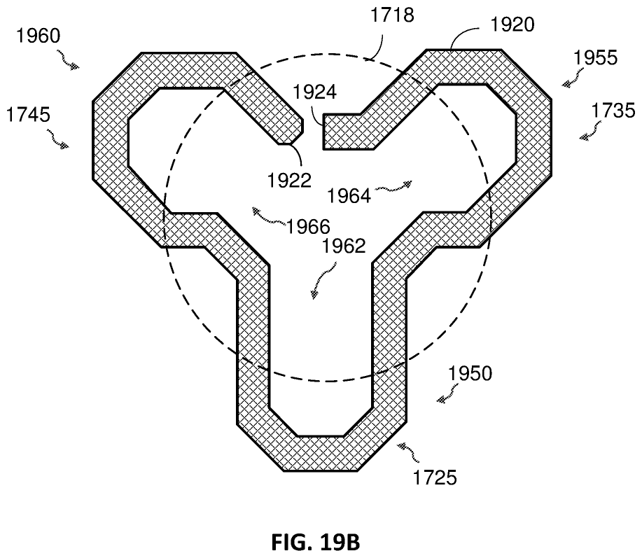

In certain aspects, the conductor path 1715 of the inductor structure 1710 is formed from two or more metal layers. The metal layers may be metal layers in a chip (i.e., die), metal layers in a substrate (e.g., laminate), and the like. In this regard, FIG. 19A shows an example of a first portion 1910 of the conductor path 1715 and FIG. 19B shows an example of a second portion 1920 of the conductor path 1715. The first portion 1910 may also be referred to as a first conductor path, and the second portion 1920 may also be referred to as a second conductor path where the conductor path 1715 includes the first and second conductor paths. Note that FIGS. 19A and 19B show the first portion 1910 and the second portion 1920 of the conductor path 1715 separately for ease of illustration.

In certain aspects, the first portion 1910 is formed from a first metal layer (e.g., using a lithographic and etching process). In this example, the first portion 1910 is contiguous in the first metal layer, and is patterned to form a first loop portion 1930, a third loop portion 1935, and a fifth loop portion 1940 corresponding to the first inductor 1720, the third inductor 1730, and the fifth inductor 1740, respectively. The second portion 1920 is formed from a second metal layer different from the first metal layer (e.g., using a lithographic and etching process). In this example, the second portion 1920 is contiguous in the second metal layer, and is patterned to form a second loop portion 1950, a fourth loop portion 1955, and a sixth loop portion 1960 corresponding to the second inductor 1725, the fourth inductor 1735, and the sixth inductor 1745, respectively. As shown in FIGS. 19A and 19B, the first loop portion 1930, the second loop portion 1950, the third loop portion 1935, the fourth loop portion 1955, the fifth loop portion 1940, and the sixth loop portion 1960 are positioned in a circular arrangement such that a circumference of the ring 1718 (i.e., circle) passes through each of the first loop portion 1930, the second loop portion 1950, the third loop portion 1935, the fourth loop portion 1955, the fifth loop portion 1940, and the sixth loop portion 1960.

In some implementations, the second metal layer is above the first metal layer, which allows the second portion 1920 of the conductor path 1715 to pass over the first portion 1910 of the conductor path 1715. In other implementations, the second metal layer is below the first metal layer, which allows the second portion 1920 of the conductor path 1715 to pass under the first portion 1910 of the conductor path 1715. The first and second metal layers may be metal layers in a chip (i.e., a die), metal layers in a substrate (e.g., a laminate, a PCB, etc.), and the like.

The first portion 1910 of the conductor path 1715 has a first end 1912 and a second end 1914. The first end 1912 corresponds to the first terminal 1712 shown in FIG. 17. In this example, the first loop portion 1930 partially encloses a first area 1942, the third loop portion 1935 partially encloses a third area 1944, and the fifth loop portion 1940 partially encloses a fifth area 1946. Current flow through the first portion 1910 causes the first loop portion 1930 to generate a magnetic field in the first area 1942, causes the third loop portion 1935 to generate a magnetic field in the third area 1944, and causes the fifth loop portion 1940 to generate a magnetic field in the fifth area 1946.

For the case where current enters the first terminal 1712, the current flows from the first end 1912 to the second end 1914 of the first portion 1910 of the conductor path 1715 in the counterclockwise direction. In this case, the first loop portion 1930, the third loop portion 1935, and the fifth loop portion 1940 generate magnetic fields in the first area 1942, the third area 1944, and the fifth area 1946 with the polarity shown in the example in FIG. 18A. It is to be appreciated that current may also flow in the opposite direction (e.g., depending on the polarity of the signal driving the inductor structure 1710).

Referring to FIG. 19B, the second portion 1920 of the conductor path 1715 has a first end 1922 and a second end 1924. The second end 1924 corresponds to the second terminal 1714 shown in FIG. 17. As discussed further below, the first end 1922 is coupled to the second end 1914 of the first portion 1910 (e.g., by one or more vias 1916 disposed between the first metal layer and the second metal layer). In this example, the second loop portion 1950 partially encloses a second area 1962, the fourth loop portion 1955 partially encloses a fourth area 1964, and the sixth loop portion 1960 partially encloses a sixth area 1966. Current flow through the second portion 1920 causes the second loop portion 1950 to generate a magnetic field in the second area 1962, causes the fourth loop portion 1955 to generate a magnetic field in the fourth area 1964, and causes the sixth loop portion 1960 to generate a magnetic field in the sixth area 1966.

For the case where current enters the first end 1922 of the second portion 1920 from the second end 1914 of the first portion 1910, the current flows from the first end 1922 to the second end 1924 of the second portion 1920 of the conductor path 1715 in the counterclockwise direction. In this case, the second loop portion 1950, the fourth loop portion 1955, and the sixth loop portion 1960 generate magnetic fields in the second area 1962, the fourth area 1964, and the sixth area 1966 with the polarity shown in the example in FIG. 18A. It is to be appreciated that current may also flow in the opposite direction (e.g., depending on the polarity of the signal driving the inductor structure 1710).

Thus, for example where the current enters the first terminal 1712, the current flows through the first portion 1910 of the conductor path 1715 in the counterclockwise direction. The current then flows from the second end 1914 of the first portion 1910 of the conductor path 1715 to the first end 1922 of the second portion 1920 of the conductor path 1715 through the one or more vias 1916. The current then flows from the first end 1922 to the second end 1924 of the second portion 1920 in the counterclockwise direction. Thus, in this example, the current flows in the counterclockwise direction in both the first portion 1910 and the second portion 1920 of the conductor path 715.

The first portion 1910 and the second portion 1920 of the conductor path 1715 are discussed above for the case where current enters the first terminal 1712 of the inductor structure 1710. For the case where current enters the second terminal 1714 of the inductor structure 1710, the current flows through the second portion 1920 of the conductor path 1715 in the clockwise direction, and flows through the first portion 1910 of the conductor path 1715 in the clockwise direction. In both cases, the current flows in the same direction in the first portion 1910 and the second portion 1920 of the conductor path 1715. Thus, the first loop portion 1930, the second loop portion 1950, the third loop portion 1935, the fourth loop portion 1955, the fifth loop portion 1940, and the sixth loop portion 1960 are coupled such that when a current flows from the first terminal 1712 to the second terminal 1714, the current flows in a same direction in the first loop portion 1930, the second loop portion 1950, the third loop portion 1935, the fourth loop portion 1955, the fifth loop portion 1940, and the sixth loop portion 1960.

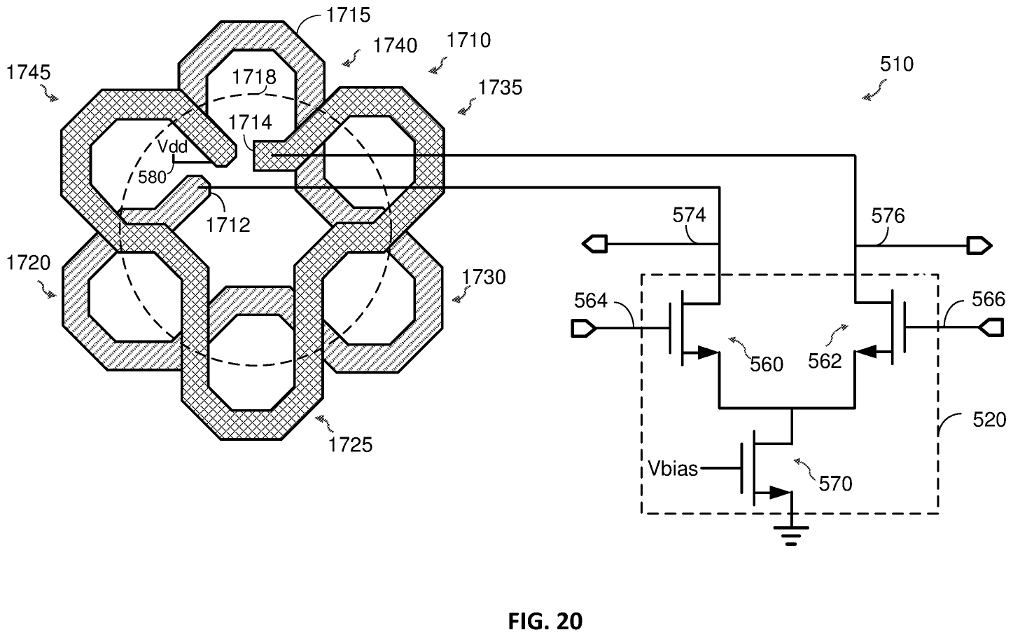

As discussed above, the inductor structure 1710 is desirable for use in a victim (e.g., an LNA, a VCO, etc.) to provide high rejection of common mode magnetic field interference from an aggressor. In this regard, FIG. 20 shows an example in which the inductor structure 1710 is used to implement the inductor 540 in the exemplary LNA 510 to reduce common mode magnetic field interference.

In this example, the first terminal 1712 of the inductor structure 1710 is coupled to the drain of the first input transistor 560, and the second terminal 1714 of the inductor structure 1710 is coupled to the drain of the second input transistor 562. Also, in this example, the inductor structure 1710 is coupled to the supply rail via the tap 580 (e.g., center tap). In this example, the first inductor 1720, the third inductor 1730, and the fifth inductor 1740 are between the first terminal 1712 and the tap 580, and the second inductor 1725, the fourth inductor 1735, and the sixth inductor 1745 are between the second terminal 1714 and the tap 580. It is to be appreciated that the input transistors 560 and 562 are not drawn to scale relative to the inductor structure 1710, and that the input transistors 560 and 562 may be much smaller than the inductor structure 1710. It is also to be appreciated that the LNA 510 may include one or more additional components (e.g., one or more capacitors) in some implementations.

In this example, the LNA 510 has a differential output including the first output 574 and the second output 576. Since the inductors 1720, 1725, 1730, 1735, 1740, and 1745 have the same magnetic polarity, the inductors 1720, 1725, 1730, 1735, 1740, and 1745 are affected approximately equally by magnetic field interference that is common to the inductors 1720, 1725, 1730, 1735, 1740, and 1745 (i.e., common mode magnetic field interference). As a result, the differential output of the LNA 510 approximately cancels out the common mode magnetic field interference. The cancelation of the common mode magnetic field interference reduces unwanted magnetic coupling to the LNA 510 from an aggressor (e.g., the PA 410).

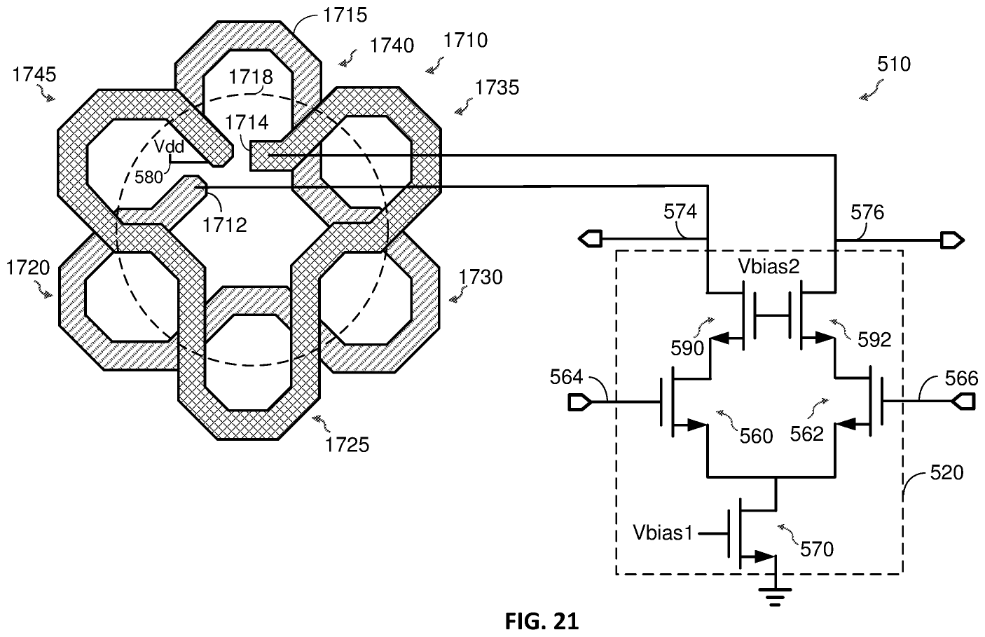

FIG. 21 shows an example where the LNA 510 includes the first cascode transistor 590 and the second cascode transistor 592. In this example, the first terminal 1712 of the inductor structure 1710 is coupled to the drain of the first cascode transistor 590, and the second terminal 1714 of the inductor structure 1710 is coupled to the drain of the second cascode transistor 592.

It is to be appreciated that the exemplary inductor structure 710 may or may not be used in conjunction with the exemplary inductor structure 1710 to reduce magnetic coupling from an aggressor (e.g., the PA 410 or VCO 310) to a victim (e.g., the LNA). For example, in some implementations, the inductor structure 710 may be used without the inductor structure 1710 in the victim (e.g., for cases where the inductor structure 710 provides a sufficient reduction in magnetic coupling to the victim without the need for the inductor structure 1710). It is to be appreciated that the exemplary inductor structure 1710 may or may not be used in conjunction with the exemplary inductor structure 710 (e.g., to increase immunity to common mode magnetic field interference from an aggressor and/or another source of magnetic field interference).

It is to be appreciated that an inductor may be physically implemented on a chip with multiple inductors coupled in series and/or parallel. It is also to be appreciated that an inductor may be physically embedded in a multi-layer substrate (e.g., laminate or PCB), which may include multiple inductors coupled in series and/or parallel. The inductors in the multi-layer substrate may be coupled to one or more flip chips through solder bumps and/or copper pillars (Cu pillars).

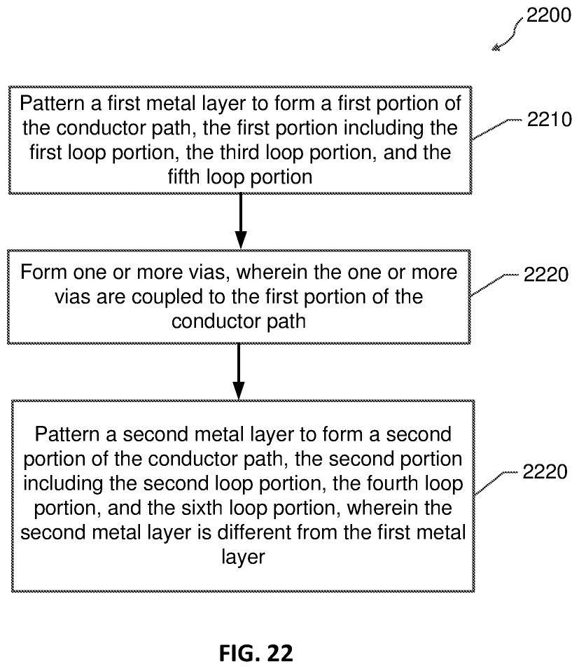

FIG. 22 is a flowchart illustrating a method 2200 of fabricating an inductor structure according to certain aspects. The inductor structure may correspond to the inductor structure 710 or the inductor structure 1710. The inductor structure includes a conductor path including a first loop portion (e.g., first loop portion 1030 or 1930), a second loop portion (e.g., second loop portion 1050 or 1950), a third loop portion (e.g., third loop portion 1035 or 1935), a fourth loop portion (e.g., 1055 or 1955), a fifth loop portion (e.g., fifth loop portion 1040 or 1940), and a sixth loop portion (e.g., sixth loop portion 1060 or 1960).

At block 2210, a first metal layer is patterned to form a first portion of the conductor path, the first portion including the first loop portion, the third loop portion, and the fifth loop portion. For example, the first metal layer may be patterned to form the first portion (e.g., first portion 1010 or 1910) using a lithographic and etching process.

At block 2220, one of more vias is formed, wherein the one or more vias are coupled to the first portion of the conductor path. The one or more vias (e.g., one or more vias 1016 or 1916) may be formed from one or more layers of conductive material (e.g., metal).

At block 2230, a second metal layer is patterned to form a second portion of the conductor path, the second portion including the second loop portion, the fourth loop portion, and the sixth loop portion, wherein the second metal layer is different from the first metal layer. For example, the second metal layer may be patterned to form the second portion (e.g., second portion 1020 or 1920) using a lithographic and etching process. The one or more vias are electrically coupled between the first portion of the conductor path and the second portion of the conductor path.

In certain aspects, the first loop portion, the third loop portion, and the fifth loop portion are contiguous in the first metal layer, and the second loop portion, the fourth loop portion, and the sixth loop portion are contiguous in the second metal layer.

The first metal layer may be above or below the second metal layer. In some implementations, the first metal layer and the second metal layer may be embedded in a substrate (e.g., a laminate, a PCB, etc.). In some implementations, the first metal layer and the second metal layer may be deposited on a semiconductor substrate with an insulating layer between the first metal layer and the second metal layer. In some implementations, portions of the insulating layer may be etched away to form one or more holes, and conductive material (e.g., one or more metals) may be deposited in the one or more holes to form the one or more vias.

It is to be appreciated that the present disclosure is not limited to the exemplary terminology used above to describe aspects of the present disclosure. For example, it is to be appreciated that magnetic coupling may also be referred to as inductive coupling or another term.

Implementation examples are described in the following numbered clauses:
1. An apparatus, comprising:
   an inductor structure having a first terminal and a second terminal, the inductor structure comprising:
   a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a first direction in the first inductor, the third inductor, and the fifth inductor, and the current flows in a second direction in the second inductor, the fourth inductor, and the sixth inductor.
2. The apparatus of clause 1, wherein the first direction is a clockwise direction, and the second direction is a counterclockwise direction.
3. The apparatus of clause 1, wherein the first direction is a counterclockwise direction, and the second direction is a clockwise direction.
4. The apparatus of any one of clauses 1 to 3, wherein the first inductor, the second inductor, the third inductor, the fourth inductor, the fifth inductor, and the sixth inductor are arranged along a circle.
5. The apparatus of any one of clauses 1 to 4, wherein the first inductor and the second inductor are adjacent to each other, the third inductor and the fourth inductor are adjacent to each other, and the fifth inductor and the sixth inductor are adjacent to each other.
6. The apparatus of any one of clauses 1 to 5, wherein the conductor path includes:
   a first portion formed from a first metal layer, wherein the first portion includes the first inductor, the third inductor, and the fifth inductor;
   a second portion formed from a second metal layer, wherein the second portion includes the second inductor, the fourth inductor, and the sixth inductor; and
   one or more vias coupling the first portion and the second portion.
7. The apparatus of clause 6, wherein the first portion is contiguous and the second portion is contiguous.
8. The apparatus of any one of clauses 1 to 7, wherein each one of the first inductor, the second inductor, the third inductor, the fourth inductor, the fifth inductor, and the sixth inductor comprises a respective loop inductor.
9. The apparatus of clause 8, wherein each respective loop inductor comprises a respective lobe inductor.
10. The apparatus of any one of clauses 1 to 9, further comprising:
   a first transistor, wherein a drain of the first transistor is coupled to the first terminal of the inductor structure, and a gate of the first transistor is configured to receive a first input signal; and
   a second transistor, wherein a drain of the second transistor is coupled to the second terminal of the inductor structure, and a gate of the second transistor is configured to receive a second input signal.
11. The apparatus of clause 10, further comprising a tap coupling the inductor structure to a supply rail, wherein the first inductor, the third inductor, and the fifth inductor are between the first terminal and the tap, and the second inductor, the fourth inductor, and the sixth inductor are between the second terminal and the tap.
12. The apparatus of clause 10 or 11, wherein the first transistor and the second transistor are located within the inductor structure.
13. The apparatus of any one of clauses 1 to 9, further comprising:
   a first transistor, wherein a gate of the first transistor is configured to receive a first input signal;
   a second transistor, wherein a gate of the second transistor is configured to receive a second input signal;
   a third transistor, wherein a drain of the third transistor is coupled to the first terminal of the inductor structure, a gate of the third transistor is coupled to a bias circuit, and a source of the third transistor is coupled to a drain of the first transistor; and
   a fourth transistor, wherein a drain of the fourth transistor is coupled to the second terminal of the inductor structure, a gate of the fourth transistor is coupled to the bias circuit, and a source of the fourth transistor is coupled to a drain of the second transistor.
14. The apparatus of clause 13, further comprising a tap coupling the inductor structure to a supply rail, wherein the first inductor, the third inductor, and the fifth inductor are between the first terminal and the tap, and the second inductor, the fourth inductor, and the sixth inductor are between the second terminal and the tap.
15. The apparatus of clause 13 or 14, wherein the first transistor and the second transistor are located within the inductor structure.
16. The apparatus of any one of clauses 1 to 9, further comprising a voltage-controlled capacitor coupled between the first terminal and the second terminal.
17. An apparatus, comprising:
   an inductor structure having a first terminal and a second terminal, the inductor structure comprising:
   a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a same direction in the first inductor, the second inductor, the third inductor, the fourth inductor, the fifth inductor, and the sixth inductor.
18. The apparatus of clause 17, wherein the direction is a clockwise direction.
19. The apparatus of clause 17, wherein the direction is a counterclockwise direction.
20. The apparatus of any one of clauses 17 to 19, wherein the first inductor, the second inductor, the third inductor, the fourth inductor, the fifth inductor, and the sixth inductor are arranged along a circle.
21. The apparatus of any one of clauses 17 to 20, wherein the conductor path includes:
   a first portion formed from a first metal layer, wherein the first portion includes the first inductor, the third inductor, and the fifth inductor; and
   a second portion formed from a second metal layer, wherein the second portion includes the second inductor, the fourth inductor, and the sixth inductor; and
   one or more vias disposed between the first portion and the second portion.
22. The apparatus of clause 21, wherein the first portion is contiguous and the second portion is contiguous.
23. The apparatus of any one of clauses 17 to 22, wherein each one of the first inductor, the second inductor, the third inductor, the fourth inductor, the fifth inductor, and the sixth inductor comprises a respective loop inductor.
24. The apparatus of clause 23, wherein each respective loop inductor comprises a respective lobe inductor.
25. The apparatus of any one of clauses 17 to 24, further comprising:
   a first transistor, wherein a drain of the first transistor is coupled to the first terminal of the inductor structure, and a gate of the first transistor is configured to receive a first input signal; and
   a second transistor, wherein a drain of the second transistor is coupled to the second terminal of the inductor structure, and a gate of the second transistor is configured to receive a second input signal.
26. The apparatus of clause 25, further comprising a tap coupling the inductor structure to a supply rail, wherein the first inductor, the third inductor, and the fifth inductor are between the first terminal and the tap, and the second inductor, the fourth inductor, and the sixth inductor are between the second terminal and the tap.
27. The apparatus of any one of clauses 17 to 24, further comprising:
   a first transistor, wherein a gate of the first transistor is configured to receive a first input signal;
   a second transistor, wherein a gate of the second transistor is configured to receive a second input signal;
   a third transistor, wherein a drain of the third transistor is coupled to the first terminal of the inductor structure, a gate of the third transistor is coupled to a bias circuit, and a source of the third transistor is coupled to a drain of the first transistor; and
   a fourth transistor, wherein a drain of the fourth transistor is coupled to the second terminal of the inductor structure, a gate of the fourth transistor is coupled to the bias circuit, and a source of the fourth transistor is coupled to a drain of the second transistor.
28. The apparatus of clause 27, further comprising a tap coupling the inductor structure to a supply rail, wherein the first inductor, the third inductor, and the fifth inductor are between the first terminal and the tap, and the second inductor, the fourth inductor, and the sixth inductor are between the second terminal and the tap.
29. An apparatus, comprising:
   an inductor structure having a first terminal and a second terminal, the inductor structure comprising a conductor path defined by:
   a first loop portion partially enclosing a first area;
   a second loop portion partially enclosing a second area;
   a third loop portion partially enclosing a third area, the second loop portion positioned between the first loop portion and the third loop portion;
   a fourth loop portion partially enclosing a fourth area, the third loop portion positioned between the second loop portion and the fourth loop portion;
   a fifth loop portion partially enclosing a fifth area, the fourth loop portion positioned between the third loop portion and the fifth loop portion; and
   a sixth loop portion enclosing partially enclosing a sixth area, the fifth loop portion positioned between the third loop portion and the sixth loop portion, wherein the first loop portion, the second loop portion, the third loop portion, the forth loop portion, the fifth loop portion, and the sixth loop portion are positioned in a circular arrangement such that a circumference of a circle passes through each of the first loop portion, the second loop portion, the third loop portion, the forth loop portion, the fifth loop portion, and the sixth loop portion.
30. The apparatus of clause 29, wherein the first area, the second area, the third area, the fourth area, the fifth area, and the sixth area are substantially non-overlapping.
31. The apparatus of clause 29 or 30, wherein the first loop portion, the second loop portion, the third loop portion, the forth loop portion, the fifth loop portion, and the sixth loop portion are coupled such that when a current flows from the first terminal to the second terminal, the current flows in a first direction in the first loop portion, the third loop portion, and the fifth loop portion, and the current flows in a second direction in the second loop portion, the fourth loop portion, and the sixth loop portion.
32. The apparatus of clause 31, wherein the first direction is a clockwise direction, and the second direction is a counterclockwise direction.
33. The apparatus of clause 31, wherein the first direction is a counterclockwise direction, and the second direction is a clockwise direction.
34. The apparatus of clause 29 or 30, wherein the first loop portion, the second loop portion, the third loop portion, the forth loop portion, the fifth loop portion, and the sixth loop portion are coupled such that when a current flows from the first terminal to the second terminal, the current flows in a same direction in the first loop portion, the second loop portion, the third loop portion, the forth loop portion, the fifth loop portion, and the sixth loop portion.
35. The apparatus of any one of clauses 29 to 34, wherein the first loop portion, the third loop portion, and the fifth loop portion are in a first metal layer, and wherein the second loop portion, the fourth loop portion, and the sixth loop portion are in a second metal layer different from the first metal layer.
36. The apparatus of clause 35, wherein the first loop portion, the third loop portion, and the fifth loop portion are contiguous in the first metal layer, and wherein the second loop portion, the fourth loop portion, and the sixth loop portion are contiguous in the second metal layer.
37. The apparatus of any one of clauses 29 to 36, further comprising:
   a first transistor, wherein a drain of the first transistor is coupled to the first terminal of the inductor structure, and a gate of the first transistor is configured to receive a first input signal; and
   a second transistor, wherein a drain of the second transistor is coupled to the second terminal of the inductor structure, and a gate of the second transistor is configured to receive a second input signal.
38. The apparatus of clause 37, further comprising a tap coupling the inductor structure to a supply rail, wherein the first loop portion, the third loop portion, and the fifth loop portion are between the first terminal and the tap, and the second loop portion, the fourth loop portion, and the sixth loop portion are between the second terminal and the tap.
39. The apparatus of clause 37 or 38, wherein the first transistor and the second transistor are located within the inductor structure.
40. The apparatus of any one of clauses 29 to 36, further comprising:
   a first transistor, wherein a gate of the first transistor is configured to receive a first input signal;
   a second transistor, wherein a gate of the second transistor is configured to receive a second input signal;
   a third transistor, wherein a drain of the third transistor is coupled to the first terminal of the inductor structure, a gate of the third transistor is coupled to a bias circuit, and a source of the third transistor is coupled to a drain of the first transistor; and
   a fourth transistor, wherein a drain of the fourth transistor is coupled to the second terminal of the inductor structure, a gate of the fourth transistor is coupled to the bias circuit, and a source of the fourth transistor is coupled to a drain of the second transistor.
41. The apparatus of clause 40, further comprising a tap coupling the inductor structure to a supply rail, wherein the first loop portion, the third loop portion, and the fifth loop portion are between the first terminal and the tap, and the second loop portion, the fourth loop portion, and the sixth loop portion are between the second terminal and the tap.
42. The apparatus of clause 40 or 41, wherein the first transistor and the second transistor are located within the inductor structure.
43. The apparatus of any one of clauses 29 to 36, further comprising a voltage-controlled capacitor coupled between the first terminal and the second terminal.
44. A method of fabricating an inductor structure, wherein the inductor structure includes a conductor path including first loop portion, a second loop portion, a third loop portion, a fourth loop portion, a fifth loop portion, and a sixth loop portion, the method comprising:
   patterning a first metal layer to form a first portion of the conductor path, the first portion including the first loop portion, the third loop portion, and the fifth loop portion;
   forming one or more vias, wherein the one or more vias are coupled to the first portion of the conductor path; and
   patterning a second metal layer to form a second portion of the conductor path, the second portion including the second loop portion, the fourth loop portion, and the sixth loop portion, wherein the second metal layer is different from the first metal layer.
45. The method of clause 44, wherein the first loop portion, the third loop portion, and the fifth loop portion are contiguous in the first metal layer, and wherein the second loop portion, the fourth loop portion, and the sixth loop portion are in contiguous in the second metal layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is to be appreciated than an “input” may be a single-ended input, a differential input, or one of two inputs of a differential input, and an “output” may be a single-ended output, a differential output, or one of two outputs of a differential output.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
an inductor structure having a first terminal and a second terminal, the inductor structure comprising:
a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a first direction in the first inductor, the third inductor, and the fifth inductor, and the current flows in a second direction in the second inductor, the fourth inductor, and the sixth inductor.

2. The apparatus of claim 1, wherein the first direction is a clockwise direction, and the second direction is a counterclockwise direction.

3. The apparatus of claim 1, wherein the first direction is a counterclockwise direction, and the second direction is a clockwise direction.

4. The apparatus of claim 1, wherein the first inductor, the second inductor, the third inductor, the fourth inductor, the fifth inductor, and the sixth inductor are arranged along a circle.

5. The apparatus of claim 1, wherein the conductor path includes:
a first portion formed from a first metal layer, wherein the first portion includes the first inductor, the third inductor, and the fifth inductor;
a second portion formed from a second metal layer, wherein the second portion includes the second inductor, the fourth inductor, and the sixth inductor; and
one or more vias coupling the first portion and the second portion.

6. The apparatus of claim 5, wherein the first portion is contiguous and the second portion is contiguous.

7. The apparatus of claim 1, wherein each one of the first inductor, the second inductor, the third inductor, the fourth inductor, the fifth inductor, and the sixth inductor comprises a respective loop inductor.

8. The apparatus of claim 1, further comprising:
a first transistor, wherein a drain of the first transistor is coupled to the first terminal of the inductor structure, and a gate of the first transistor is configured to receive a first input signal; and
a second transistor, wherein a drain of the second transistor is coupled to the second terminal of the inductor structure, and a gate of the second transistor is configured to receive a second input signal.

9. The apparatus of claim 8, wherein the first transistor and the second transistor are located within the inductor structure.

10. The apparatus of claim 1, further comprising:
a first transistor, wherein a gate of the first transistor is configured to receive a first input signal;
a second transistor, wherein a gate of the second transistor is configured to receive a second input signal;
a third transistor, wherein a drain of the third transistor is coupled to the first terminal of the inductor structure, a gate of the third transistor is coupled to a bias circuit, and a source of the third transistor is coupled to a drain of the first transistor; and
a fourth transistor, wherein a drain of the fourth transistor is coupled to the second terminal of the inductor structure, a gate of the fourth transistor is coupled to the bias circuit, and a source of the fourth transistor is coupled to a drain of the second transistor.

11. The apparatus of claim 10, wherein the first transistor and the second transistor are located within the inductor structure.

12. The apparatus of claim 1, further comprising a voltage-controlled capacitor coupled between the first terminal and the second terminal.

13. An apparatus, comprising:
an inductor structure having a first terminal and a second terminal, the inductor structure comprising:
a conductor path between the first terminal and the second terminal, wherein the conductor path includes a first inductor, a second inductor, a third inductor, a fourth inductor, a fifth inductor, and a sixth inductor, and wherein the conductor path is configured such that, when a current flows from the first terminal to the second terminal, the current flows in a same direction in the first inductor, the second inductor, the third inductor, the fourth inductor, the fifth inductor, and the sixth inductor.

14. The apparatus of claim 13, wherein the first inductor, the second inductor, the third inductor, the fourth inductor, the fifth inductor, and the sixth inductor are arranged along a circle.

15. The apparatus of claim 13, wherein the conductor path includes:
a first portion formed from a first metal layer, wherein the first portion includes the first inductor, the third inductor, and the fifth inductor; and
a second portion formed from a second metal layer, wherein the second portion includes the second inductor, the fourth inductor, and the sixth inductor; and
one or more vias disposed between the first portion and the second portion.

16. The apparatus of claim 15, wherein the first portion is contiguous and the second portion is contiguous.

17. The apparatus of claim 1, wherein each one of the first inductor, the second inductor, the third inductor, the fourth inductor, the fifth inductor, and the sixth inductor comprises a respective loop inductor.

18. The apparatus of claim 13, further comprising:
a first transistor, wherein a drain of the first transistor is coupled to the first terminal of the inductor structure, and a gate of the first transistor is configured to receive a first input signal; and
a second transistor, wherein a drain of the second transistor is coupled to the second terminal of the inductor structure, and a gate of the second transistor is configured to receive a second input signal.

19. The apparatus of claim 13, further comprising:
a first transistor, wherein a gate of the first transistor is configured to receive a first input signal;
a second transistor, wherein a gate of the second transistor is configured to receive a second input signal;
a third transistor, wherein a drain of the third transistor is coupled to the first terminal of the inductor structure, a gate of the third transistor is coupled to a bias circuit, and a source of the third transistor is coupled to a drain of the first transistor; and
a fourth transistor, wherein a drain of the fourth transistor is coupled to the second terminal of the inductor structure, a gate of the fourth transistor is coupled to the bias circuit, and a source of the fourth transistor is coupled to a drain of the second transistor.

20. An apparatus, comprising:
an inductor structure having a first terminal and a second terminal, the inductor structure comprising a conductor path defined by:
a first loop portion partially enclosing a first area;
a second loop portion partially enclosing a second area;
a third loop portion partially enclosing a third area, the second loop portion positioned between the first loop portion and the third loop portion;
a fourth loop portion partially enclosing a fourth area, the third loop portion positioned between the second loop portion and the fourth loop portion;
a fifth loop portion partially enclosing a fifth area, the fourth loop portion positioned between the third loop portion and the fifth loop portion; and
a sixth loop portion enclosing partially enclosing a sixth area, the fifth loop portion positioned between the third loop portion and the sixth loop portion, wherein the first loop portion, the second loop portion, the third loop portion, the forth loop portion, the fifth loop portion, and the sixth loop portion are positioned in a circular arrangement such that a circumference of a circle passes through each of the first loop portion, the second loop portion, the third loop portion, the forth loop portion, the fifth loop portion, and the sixth loop portion.

21. The apparatus of claim 20, wherein the first area, the second area, the third area, the fourth area, the fifth area, and the sixth area are substantially non-overlapping.

22. The apparatus of claim 20, wherein the first loop portion, the second loop portion, the third loop portion, the forth loop portion, the fifth loop portion, and the sixth loop portion are coupled such that when a current flows from the first terminal to the second terminal, the current flows in a first direction in the first loop portion, the third loop portion, and the fifth loop portion, and the current flows in a second direction in the second loop portion, the fourth loop portion, and the sixth loop portion.

23. The apparatus of claim 22, wherein the first direction is a clockwise direction, and the second direction is a counterclockwise direction.

24. The apparatus of claim 22, wherein the first direction is a counterclockwise direction, and the second direction is a clockwise direction.

25. The apparatus of claim 20, wherein the first loop portion, the second loop portion, the third loop portion, the forth loop portion, the fifth loop portion, and the sixth loop portion are coupled such that when a current flows from the first terminal to the second terminal, the current flows in a same direction in the first loop portion, the second loop portion, the third loop portion, the forth loop portion, the fifth loop portion, and the sixth loop portion.

26. The apparatus of claim 20, wherein the first loop portion, the third loop portion, and the fifth loop portion are in a first metal layer, and wherein the second loop portion, the fourth loop portion, and the sixth loop portion are in a second metal layer different from the first metal layer.

27. The apparatus of claim 26, wherein the first loop portion, the third loop portion, and the fifth loop portion are contiguous in the first metal layer, and wherein the second loop portion, the fourth loop portion, and the sixth loop portion are contiguous in the second metal layer.

28. The apparatus of claim 20, further comprising:
a first transistor, wherein a drain of the first transistor is coupled to the first terminal of the inductor structure, and a gate of the first transistor is configured to receive a first input signal; and
a second transistor, wherein a drain of the second transistor is coupled to the second terminal of the inductor structure, and a gate of the second transistor is configured to receive a second input signal.

29. The apparatus of claim 20, further comprising:
a first transistor, wherein a gate of the first transistor is configured to receive a first input signal;
a second transistor, wherein a gate of the second transistor is configured to receive a second input signal;
a third transistor, wherein a drain of the third transistor is coupled to the first terminal of the inductor structure, a gate of the third transistor is coupled to a bias circuit, and a source of the third transistor is coupled to a drain of the first transistor; and
a fourth transistor, wherein a drain of the fourth transistor is coupled to the second terminal of the inductor structure, a gate of the fourth transistor is coupled to the bias circuit, and a source of the fourth transistor is coupled to a drain of the second transistor.

30. The apparatus of claim 20, further comprising a voltage-controlled capacitor coupled between the first terminal and the second terminal.
